(19) United States
(12) Patent Application Publication
(10) Pub. No.: US 2026/0342258 A1
(43) Pub. Date: Oct. 29, 2026

(54) MOTOR DRIVE CONTROL DEVICE AND METHOD FOR DETECTING IDLING OF MOTOR

(71) Applicant: MINEBEA MITSUMI Inc., Nagano (JP)

(72) Inventor: Hidetoshi HIJIKATA, Kitasaku-gun, Nagano (JP)

(21) Appl. No.: 19/543,051

(22) Filed: Feb. 18, 2026

(30) Foreign Application Priority Data
Feb. 19, 2025 (JP) 2025-025252
Oct. 10, 2025 (JP) 2025-172228

(51) Int. Cl. H02P 23/14

(52) U.S. Cl. CPC H02P 23/14

(57) ABSTRACT

A motor drive control device includes: a control circuit configured to generate a drive control signal; and a neutral point voltage detection circuit configured to detect a neutral point detection voltage obtained by combining phase voltages of all phases among respective phase voltages generated between an inverter circuit including switches provided corresponding to coils of respective phases of a motor and the coils of the respective phases of the motor, wherein the control circuit generates an idling control signal, when the rotor of the motor is idling, generates currents circulating between the coils of the motor and the inverter circuit by switching a switch state of the inverter circuit, and then determines the motor based on a neutral point detection voltage generated the neutral point voltage detection circuit by inductive kickback generated when a path of the currents is interrupted.

### CROSS REFERENCE TO RELATED APPLICATIONS

This application claims priority benefit of Japanese Patent Application No. 2025-025252 filed on Feb. 19, 2025, and Japanese Patent Application No. 2025-172228 filed on Oct. 10, 2025. The above-referenced application is hereby incorporated herein by reference in its entirety.

### TECHNICAL FIELD

The present invention relates to a motor drive control device and a method for detecting idling of a motor.

### BACKGROUND ART

Generally, in a motor (hereinafter also referred to as "fan motor") used for a fan for cooling the inside of an electronic device such as a server, even when the motor is not driven by a drive circuit for driving the motor, the motor may be in a rotating state, so-called an idling state, due to inertia or the action of external force.

Patent Document 1 describes a method for detecting the idling state of a rotor (rotating part) of the motor. This method, upon energizing predetermined switching elements among a plurality of switching elements constituting an inverter circuit of a motor, allows detection of a rotational speed of a fan of an outdoor unit in the idling state due to external force even when an air conditioner is stopped, by extracting a rotational speed of the motor based on currents flowing through current detection resistors.

### CITATION LIST

### Patent Literature

Patent Document 1: JP 2018-170928 A

### SUMMARY OF INVENTION

### Technical Problem

However, although the method described in Patent Document 1 detects the rotational speed of the motor in the idling state, it may be only required to detect the presence or absence of an idling state of the motor in a short time without detecting the rotational speed of the idling motor. For example, when the rotor of the motor is idling, an induced electromotive force is generated, and then when a coil and the inverter circuit of the motor do not form a closed circuit, an induced voltage is periodically generated the coil (winding) of the motor, and when the coil and the inverter circuit of the motor form a closed circuit, an induced current is periodically generated the coil of the motor. At this time, the winding resistance measurement, the initial position detection of the rotor, and the like using current flowing through a shunt resistor by energizing the coil of the motor are adversely affected by the periodic change of the induced voltage and the induced current, and thus it is necessary to perform the measurement, the detection, and the like when the motor is not idling. Thus, the presence or absence of the idling state of the motor can be used as a determination index for executing various processing.

In addition, the presence or absence of the idling state of the motor can be easily detected by using a position sensor. However, if the presence or absence of the idling state of the motor can be detected without using the position sensor, it is preferable from the standpoint of simplifying a device configuration.

In addition, when detecting the idling of the motor by using a phase voltage, in the conventional method, all the switching elements constituting the inverter circuit are turned off, so that the presence or absence of an idling state of the rotor can be detected by using a zero-cross of a differential voltage between an induced voltage generated each coil (winding) by rotation of the rotor and a neutral point voltage obtained by combining voltages of all coils (windings) in the same way as the motor is driven. However, in the case of low speed, the induced voltage generated is small and the detection time between the zero-crosses is long, and thus the detectable minimum rotational speed is limited, and consequently, the idling of the motor cannot be determined stably in a short time.

Thus, a motor drive control device capable of stably detecting the presence or absence of an idling state of a motor in a short time with a simple configuration without using a position sensor is desired.

To solve the above problem, it is an object of the present invention to provide a motor drive control device capable of stably detecting the presence or absence of an idling state of a motor in a short time without using a position sensor.

### Solution to Problem

A motor drive control device according to a representative embodiment of the present invention includes: a control circuit configured to generate a drive control signal drive a motor including a coil of at least one phase; a drive circuit including an inverter circuit including a high-side switch and a low-side switch, the high-side switch and the low-side switch being provided corresponding to a coil of each phase of the motor and connected in series with each other, the drive circuit being configured to rotate a rotor of the motor by alternately turning the high-side switch and the low-side switch on and off in response to the drive control signal to switch an energization direction of the coil of corresponding phase; and a neutral point voltage detection circuit configured to detect a neutral point detection voltage obtained by combining phase voltages of all phases among respective phase voltages generated between the inverter circuit and the coils of the respective phases of the motor, wherein

the control circuit generates an idling control signal instead of the drive control signal, and when the rotor of the motor is idling, generates induced currents circulating between the coils of the motor and the inverter circuit by switching a switch state of the inverter circuit, and then determines the motor based on a neutral point detection voltage generated the neutral point voltage detection circuit by inductive kickback generated the inverter circuit when a path of the induced currents is interrupted.

### Advantageous Effects of Invention

One aspect of the present invention enables a motor drive control device to stably detect the presence or absence of an idling state of a motor in a short time without using a position sensor.

### BRIEF DESCRIPTION OF DRAWINGS

FIG. 1 is a diagram illustrating a configuration of a motor unit 100 including a motor drive control device 1 according to a first embodiment.

FIG. 2 is a diagram for explaining a switch state corresponding to a free mode, the switch state being switched by an idling control signal Id.

FIG. 3 is a diagram for explaining an example of a switch state corresponding to a charge mode, the switch state being switched by the idling control signal Id.

FIG. 4 is a diagram for explaining an example of a switch state corresponding to a discharge mode, the switch state being switched by the idling control signal Id.

FIG. 5 is a diagram for explaining another example of the switch state corresponding to the charge mode, the switch state being switched by the idling control signal Id.

FIG. 6 is a diagram for explaining another example of the switch state corresponding to the discharge mode, the switch state being switched by the idling control signal Id.

FIG. 7 is a diagram illustrating a functional block configuration of a control circuit 1 in the motor drive control device 10 according to the first embodiment.

FIG. 8 is a diagram illustrating an example of a configuration of a differential voltage determination unit 1.

FIG. 9 is a diagram illustrating an example of a configuration of a voltage measurement unit 17.

FIG. 10 is a timing chart illustrating an example of signal waveforms from power-on of the motor unit 100 in a motor stop state, through input of a speed command signal Sc, until completion of idling determination.

FIG. 11 is a timing chart illustrating an example of signal waveforms from power-on of the motor unit 100 in a motor idling state, through of the speed command signal Sc, until completion of idling determination.

FIG. 12 is a timing chart illustrating another example of signal waveforms from power-on of the motor unit 100 in the motor stop state, through input of the speed command signal Sc, until completion of idling determination.

FIG. 13 is a timing chart illustrating another example of signal waveforms from power-on of the motor unit 100 in the motor idling state, through input of the speed command signal Sc, until completion of idling determination.

FIG. 14 is a flowchart illustrating an example of a flow of processing upon power-on in the control circuit 1 of the motor drive control device 10 according to the first embodiment.

FIG. 15 is a flowchart illustrating an example of a flow of idling detection processing by switching of a low-side switch.

FIG. 16 is a flowchart illustrating an example of a flow of idling detection processing by switching of a high-side switch.

FIG. 17 is a diagram illustrating a configuration of a motor unit 100A including a motor drive control device 10A according to a second embodiment.

FIG. 18 is a diagram illustrating an example of a configuration of a current detection circuit 2c of the motor drive control device 10A according to the second embodiment.

FIG. 19 is a diagram illustrating a functional block configuration of a control circuit 1A in the motor drive control device 10A according to the second embodiment.

FIG. 20 is a diagram illustrating an example of a configuration of a voltage measurement unit 17A.

FIG. 21 is a timing chart illustrating an example of signal waveforms from the motor unit 100A in the motor stop state and the speed command signal Sc is input until completion of idling determination.

FIG. 22 is a timing chart illustrating an example of signal waveforms from power-on of the motor unit 100A in the motor idling state, through input of the speed command signal Sc, until completion of idling determination.

FIG. 23 is a timing chart illustrating another example of signal waveforms from power-on of the motor unit 100A in the motor stop state, through input of the speed command signal Sc, until completion of idling determination.

FIG. 24 is a timing chart illustrating another example of signal waveforms from power-on of the motor unit 100A in the motor idling state, through input of the speed command signal Sc, until completion of idling determination.

FIG. 25 is a flowchart illustrating an example of a flow of processing upon power-on in the control circuit 1A of the motor drive control device 10A according to the second embodiment.

FIG. 26 is a flowchart illustrating an example of a flow of current offset measurement processing.

FIG. 27 is a flowchart illustrating an example of a flow of idling detection processing by switching of the low-side switch.

FIG. 28 is a flowchart illustrating an example of a flow of idling detection processing by switching of the high-side switch.

### DESCRIPTION OF EMBODIMENTS

### 1. Overview of Embodiments

First, an outline of a representative embodiment of the invention disclosed in the present application will be described. Note that, in the following description, as an example, reference signs in the drawings corresponding to the components of the invention are indicated in parentheses.

[1] A motor drive control device (10) according to a representative embodiment of the present invention includes:
a control circuit (1) configured to generate a drive control signal (Sd) drive a motor including a coil of at least one phase;
a drive circuit (2) including an inverter circuit (2a) including a high-side switch (Q1, Q3, Q5) and a low-side switch (Q2, Q4, Q6), the high-side switch and the low-side switch being provided corresponding to a coil of each phase of the motor (3) and connected in series with each other, the drive circuit being configured to rotate a rotor of the motor by alternately turning the high-side switch and the low-side switch on and off in response to the drive control signal to switch an energization direction of the coil of corresponding phase; and
a neutral point voltage detection circuit (5) configured to detect a neutral point detection voltage (Vcom) obtained by combining phase voltages of all phases among respective phase voltages generated between the inverter circuit and the coils of the respective phases of the motor, wherein
the control circuit generates an Idling control signal (Id) instead of the drive control signal, and when the rotor of the motor is idling, generates induced currents circulating between the coils of the motor and the inverter circuit by switching a switch state of the inverter circuit, and then determines the motor based on a neutral point detection voltage generated the neutral point voltage detection circuit by inductive kickback generated the inverter circuit when a path of the induced currents is interrupted.

[2] In the motor drive control device according to above [1], the control circuit may include: a first switching unit (21a) configured to switch from a first switch state with all of the high-side switches and the low-side switches included in the inverter circuit turned off to a second switch state with all of either the high-side switches or the low-side switches included in the inverter circuit turned on; a second switching unit (21b) configured to switch from the second switch state to the first switch state; and an idling determination unit (22) configured to determine the motor based on the neutral point detection voltage generated the neutral point voltage detection circuit when switching from the second switch state to the first switch state.

[3] In the motor drive control device according to above [2], the idling determination unit may set, as a reference voltage, the neutral point detection voltage detected the neutral point voltage detection circuit in the second switch state.

[4] In the motor drive control device according to above [3], when switching from the second switch state to the first switch state, the neutral point detection voltage detected the neutral point voltage detection circuit may be used as a measured voltage, a difference between the reference voltage and the measured voltage is calculated, and when the calculated difference is larger than a predetermined idling threshold value, the motor may be determined to be in an idling state.

[5] The motor drive control device (10A) according to above [4], further including a shunt resistor (Rs) provided between the inverter circuit and a ground, and a current detection circuit (2c) configured to generate a current detection signal (Vshunt) a voltage signal corresponding to a current flowing through the shunt resistor,

the control circuit (1A) may include a voltage measurement unit (17A) configured to measure voltage value of the neutral point detection voltage and the current detection signal, and the voltage measurement unit may measure the voltage value of the neutral point detection voltage at a first timing when switching from the second switch state to the first switch state, and thereafter measure the voltage value of the current detection signal.

[6] A method for detecting idling of a motor according to a representative embodiment of the present invention is a method for detecting idling of a motor to be executed in a motor drive control device (10) including:
a control circuit (1) configured to generate a drive control signal (Sd) drive a motor (3) including a coil of at least one phase;
a drive circuit (2) including an inverter circuit (2a) including a high-side switch (Q1, Q3, Q5) and a low-side switch (Q2, Q4, Q6), the high-side switch and the low-side switch being provided corresponding to a coil of each phase of the motor and connected in series with each other, the drive circuit being configured to rotate a rotor of the motor by alternately turning the high-side switch and the low-side switch on and off in response to the drive control signal to switch an energization direction of the coil of corresponding phase; and
a neutral point voltage detection circuit (5) configured to detect a neutral point detection voltage (Vcom) obtained by combining phase voltages of all phases among respective phase voltages generated between the inverter circuit and the coils of the respective phases of the motor, the method including:
   a first step of switching from a first switch state with all of the high-side switches and the low-side switches included in the inverter circuit turned off to a second switch state with all of either the high-side switches or the low-side switches included in the inverter circuit turned on;
   a second step of switching from the second switch state to the first switch state; and
   a third step of determining the motor based on the neutral point detection voltage generated the neutral point voltage detection circuit when switching to the first switch state.

### 2. Specific Examples of Embodiments

Specific examples of embodiments of the present invention will be described below with reference to the drawings. Note that, in the following description, components common to the respective embodiments are denoted by the same reference signs, and repeated descriptions thereof will be omitted.

### FIRST EMBODIMENT

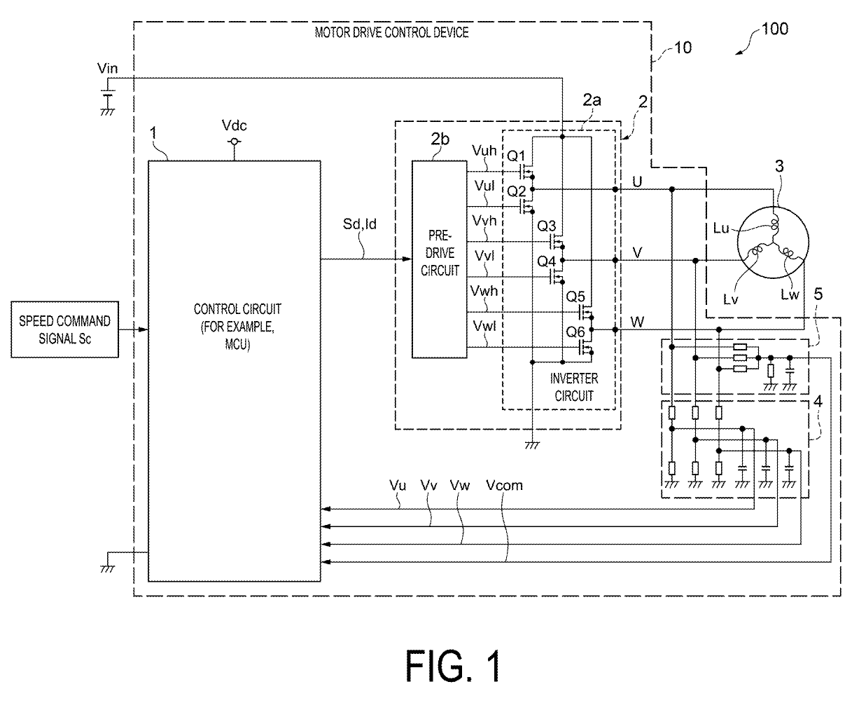

FIG. 1 is a diagram illustrating a configuration of a motor unit 100 including a motor drive control device 10 according to a first embodiment.

As illustrated in FIG. 1, the motor unit 100 includes a motor 3 and the motor drive control device 10 for controlling rotation of the motor 3. The motor unit 100 is applicable to various devices us a motor as a driving source such as fans and drones (unmanned aerial vehicles), for example.

The motor 3 is, for example, a permanent magnet synchronous motor (PMSM). In the present embodiment, the motor 3 is, for example, a surface magnet synchronous motor (SPMSM) having three-phase coils (windings) Lu, Lv, and Lw. The coils Lu, Lv, and Lw are, for example, Y (star) connected to each other. In this case, the coils may also be Δ (delta) connected to each other.

The motor drive control device 10, by applying, for example, a 120-degree energization rectangular wave drive signal to the motor 3, periodically supplies a drive current to the 3-phase coils Lu, Lv, and Lw of the motor 3 to rotate a rotor of the motor 3.

The motor drive control device 10 includes a control circuit 1, a drive circuit 2, a phase voltage detection circuit 4, and a neutral point voltage detection circuit 5.

Note that the components of the motor drive control device 10 illustrated in FIG. 1 are some of the entire components, and the motor drive control device 10 may include other components in addition to the components illustrated in FIG. 1.

The drive circuit 2 drives the motor 3 based on a drive control signal Sd output from the control circuit 1 described below. The drive circuit 2 includes, for example, an inverter circuit 2a and a pre-drive circuit 2b.

The inverter circuit 2a is a circuit disposed between a DC power supply Vin and a ground potential and configured to drive the coils Lu, Lv, and Lw of the motor 3 as a load on the basis of the input drive control signal Sd. Specifically, in an embodiment, the inverter circuit 2a includes three switching legs each including two drive transistors connected in series, and drives the motor 3 as a load based on the input drive control signal Sd by alternately turning the two drive transistors on and off (switching operation).

More specifically, the inverter circuit 2a includes switching legs corresponding to the U, V, and W phases of the motor 3, respectively. As illustrated in FIG. 1, the switching legs corresponding to respective phases include, respectively, two drive transistors (hereinafter referred to also as "switching elements") Q1 and Q2, Q3 and Q4, and Q5 and Q6 connected in series between the DC power supply Vin and the ground potential.

Here, the drive transistors Q1, Q3, and Q5 (corresponding to high-side switches) of the upper arms of the coils of the motor 3 are, for example, N-channel MOSFETs, and the drive transistors Q2, Q4, and Q6 (corresponding to low-side switches) of the lower arms of the coils of the motor 3 are, for example, N-channel MOSFETs. Note that the drive transistors Q1 to Q6 may also be other types of FETs, for example, other types of transistors such as IGBT (Insulated Gate Bipolar Transistor).

For example, the switching leg corresponding to the U-phase includes the switching elements Q1 and Q2 connected in series with each other. The point commonly connecting the switching element Q1 and the switching element Q2 is connected to one end of the coil Lu as a load. The switching leg corresponding to the V-phase includes the switching elements Q3 and Q4 connected in series with each other. The point commonly connecting the switching element Q3 and the switching element Q4 is connected to one end of the coil Lv as a load. The switching leg corresponding to the W-phase includes the switching elements Q5 and Q6 connected in series with each other. The point commonly connecting the switching element Q5 and the switching element Q6 is connected to one end of the coil Lw as a load. In addition, the switching elements Q1 and Q2, Q3 and Q4, Q5 and Q6 each have parasitic diode characteristics in a direction from the ground side toward the power supply side (not illustrated in FIG. 1).

The pre-drive circuit 2b generates a drive signal for driving the inverter circuit 2a based on the drive control signal Sd output from the control circuit 1.

The drive control signal Sd is a signal for controlling driving of the motor 3 and is, for example, a Pulse Width Modulation (PWM) signal. Specifically, the drive control signal Sd is a signal for switching energization patterns of the coils Lu, Lv, and Lw of the motor 3 determined by the on/off state of each switching element constituting the inverter circuit 2a. More specifically, the drive control signal Sd includes six types of PWM signals corresponding to the respective switching elements Q1 to Q6 of the inverter circuit 2a.

Based on the six types of PWM signals as the drive control signal Sd supplied from the control circuit 1, the pre-drive circuit 2b generates six types of drive signals Vuh, Vul, Vvh, Vvl, Vwh, and Vwl capable of supplying sufficient power to drive control electrodes (gate electrodes) of the respective switching elements Q1 to Q6 of the inverter circuit 2a.

When these drive signals Vuh, Vul, Vvh, Vvl, Vwh, and Vwl are input to the control electrodes (gate electrodes) of the respective switching elements Q1 to Q6 of the inverter circuit 2a, the respective switching elements Q1 to Q6 perform on/off operations (switching operations). For example, the switching elements Q1, Q3, and Q5 of the upper arms and the switching elements Q2, Q4, and Q6 of the lower arms of the switching legs corresponding to the respective phases alternately perform the on/off operations. Thus, power is supplied from the DC power supply Vin to each phase of the motor 3, thereby rotating the motor 3.

A wiring (hereinafter also referred to as "phase voltage detection circuit") for measuring a phase voltage generated each phase is connected between the inverter circuit 2a and the coil Lu, Lv, Lw of the corresponding phase of the motor 3, and is input to the control circuit 1. The phase voltage detection circuit 4 may include a voltage division circuit and a delay circuit, and phase detection voltages Vu, Vv, and Vw of the respective phases are generated from the phase voltages of the respective phases. In addition, a wiring (hereinafter also referred to as a "neutral point voltage detection circuit 5") for measuring a neutral point voltage obtained by combining phase voltages of all phases among the respective phase voltages is provided to branch from the wiring for measuring the phase voltages of the respective phases, and is input to the control circuit 1. The neutral point voltage detection circuit 5 is configured by a combining circuit, and may include a voltage division circuit and a delay circuit, and a neutral point detection voltage Vcom is generated from the neutral point voltage. In the control circuit 1, a differential voltage (a voltage difference between a neutral point detection voltage and a phase detection voltage of one selected phase: a value corresponding to a phase voltage of the selected phase) measured based on the phase detection voltages Vu, Vv, and Vw generated the respective phases is used during drive control of the motor described below, and the neutral point detection voltage is used during idling detection of the motor.

In driving the motor, the control circuit 1 generates the drive control signal Sd for driving the motor 3 based on, for example, a speed command signal Sc input from the outside and indicating a target operation state of the motor 3, and controls the drive of the motor 3. Specifically, the control circuit 1 generates the drive control signal Sd such that the motor 3 enters an operation state specified by the speed command signal Sc, and provides the generated drive control signal Sd to the drive circuit 2.

In the idling detection of the motor, the control circuit 1 generates an idling control signal Id described below instead of the drive control signal Sd and detects the idling of the motor 3. Specifically, when the motor 3 is not driven by the drive control signal Sd, the control circuit 1 generates the idling control signal Id such that each of the switching elements Q1 to Q6 of the inverter circuit 2a enters a switch state specified by the idling control signal Id, and provides the generated idling control signal Id to the drive circuit 2.

Here, switch states of the respective switching elements Q1 to Q6 of the inverter circuit 2a corresponding to three modes (free mode, charge mode, discharge mode) for detecting idling of the motor 3, switched by the idling control signal Id generated by the control circuit 1, will be described.

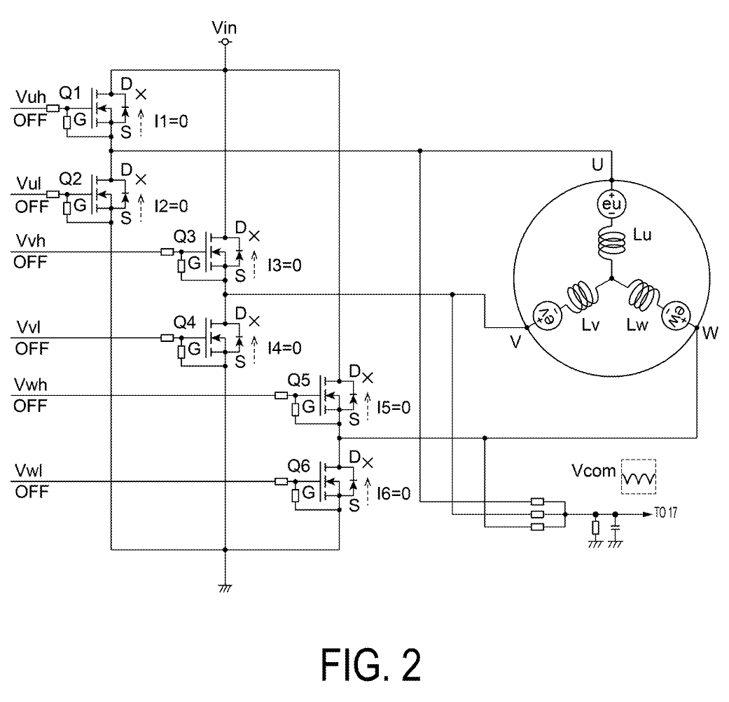

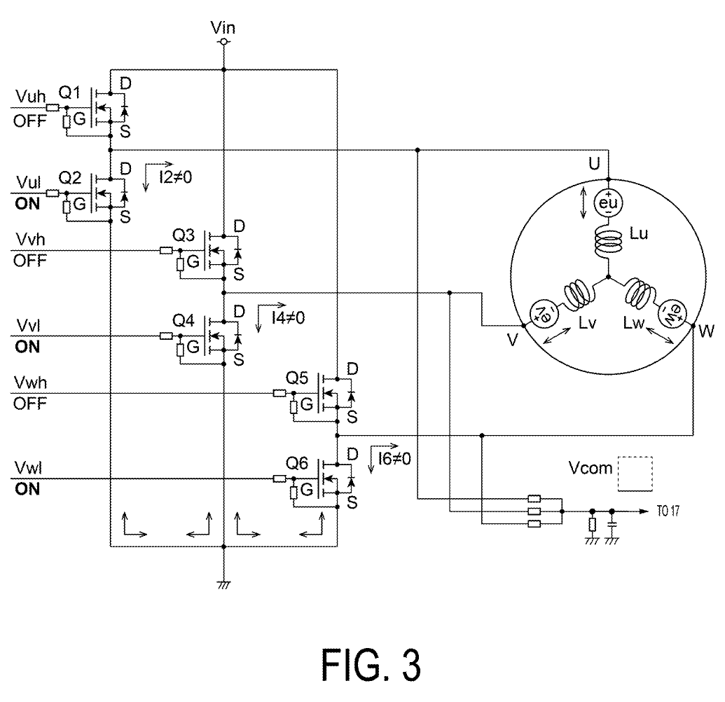

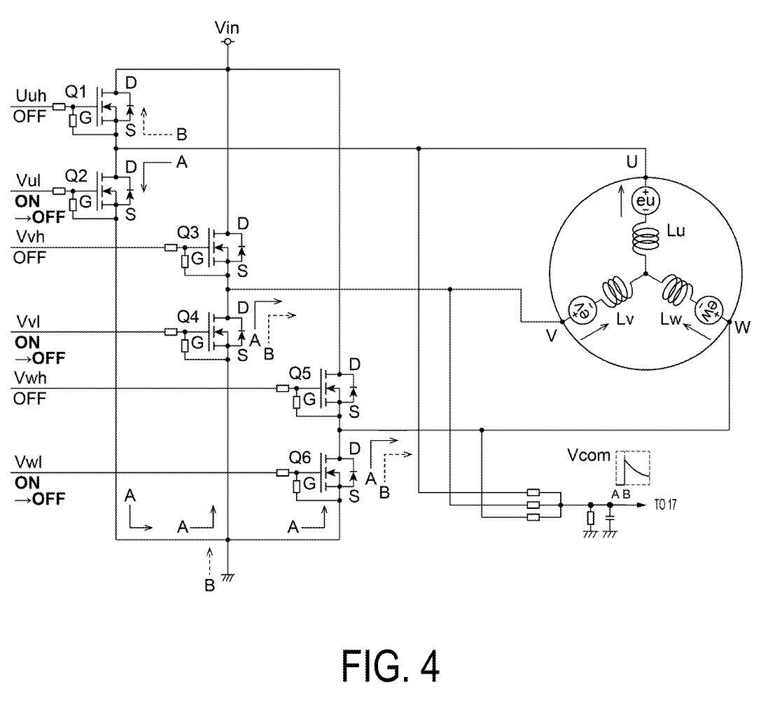

FIGS. 2-6 are diagrams for explaining respective switch states switched by the idling control signal Id. The idling control signal Id includes a signal for switching the low-side switch and a signal for switching the high-side switch, but FIG. 2 illustrates a common initial state, and therefore, a case where switching of the low-side switches is performed will be described first. In FIGS. 3 and 4, during idling detection by switching of the low-side switches, states of currents flowing, when the motor 3 is idling, in the coils of the motor 3 and the inverter circuit 2a are indicated by arrows. In FIGS. 2-6, the inverter circuit 2a is connected to the DC power supply Vin and also connected to the ground. In addition, the wiring (the neutral point voltage detection circuit 5) for the control circuit 1 to measure a neutral point voltage is connected between a corresponding phase of the coil of the motor 3 and the inverter circuit 2a. Note that the wiring (the phase voltage detection circuit 4) for the control circuit 1 to measure a phase voltage of each phase is connected between a corresponding phase of the coil of the motor 3 and the inverter circuit 2a but is not used for idling detection and therefore is not illustrated in FIGS. 2-6.

The idling control signal Id is a signal for switching to the corresponding switch state in the order of the free mode (FIG. 2), the charge mode (FIG. 3), and the discharge mode (FIG. 4). Specifically, the idling control signal Id sets the switch state of the control electrode (gate electrode) of each of the switching elements Q1 to Q6 of the inverter circuit 2a from a first switch state (corresponding to the free mode) illustrated in FIG. 2 to a second switch state (corresponding to the charge mode) illustrated in FIG. 3, and switches the switch state to the first switch state (corresponding to the discharge mode) again as illustrated in FIG. 4, thereby enabling detection of the idling of the motor 3.

### Free Mode

After power-on, when the idling control signal Id is output from the control circuit 1 at a predetermined timing on the basis of the speed command signal Sc, the control electrodes (gate electrodes) of the respective switching elements Q1 to Q6 of the inverter circuit 2a are switched to the first switch state by the idling control signal Id output from the control circuit 1. Specifically, as illustrated in FIG. 2, in the inverter circuit 2a, all switch states of the switching elements Q1 to Q6 are switched to off.

As illustrated in FIG. 2, in this first switch state, when the rotor of the motor 3 is idling, an induced electromotive force is generated the coil of each phase, and an induced voltage corresponding to an idling rotational speed is periodically generated a phase voltage of each phase (a positive-side saddle wave). However, an induced current circulating between the coils of the motor 3 and the inverter circuit 2a is not generated due to the switching elements Q1 to Q6 being turned off and clamping by the parasitic diodes. At this time, an induced voltage having an amplitude corresponding to an idling rotational speed and a period three times a period of the phase voltage is generated the neutral point voltage detection circuit 5. (Positive-side full-wave rectified wave) The positive-side saddle wave refers to a waveform similar to the full-wave rectified wave and having a recess at the apex of the positive-side arc. A positive-side full-wave rectified wave refers to a full-wave rectified wave having an arc-shaped apex at the positive side.

### Charge Mode

Next, the control electrodes (gate electrodes) of the respective switching elements Q1 to Q6 of the inverter circuit 2a are switched from the first switch state to the second switch state by the idling control signal Id output from the control circuit 1. The second switch state is a switch state where, when the rotor of the motor 3 is idling, an induced electromotive force is generated the coil of each phase, and the generated induced current circulates in a closed circuit formed by the coil and the switching element on among the switching elements Q1 to Q6. Specifically, in the inverter circuit 2a, the first switch state where all of the switch states of the respective switching elements Q1 to Q6 are off is switched to the second switch state where the switch states of only the switching elements Q2, Q4, and Q6 of the lower arms among the respective switching elements Q1 to Q6 are on, for example, as illustrated in FIG. 3.

As illustrated in FIG. 3, in the inverter circuit 2a, once the second switch state is reached turning on the switch states of the switching elements Q2, Q4, and Q6 of the lower arms among the switching elements Q1 to Q6, when the rotor of the motor 3 is idling, induced currents circulating between the coils of the motor 3 and the inverter circuit 2a are generated the coils of respective phases, and the generated induced currents circulate in the closed circuit formed by the coils and the switching elements Q2, Q4, and Q6 of the lower arms on. At this time, the phase voltage of each phase is not affected by the induced voltage because the switching element of the lower arm is on, and thus changes to 0 (zero) V. The neutral point voltage obtained by combining the phase voltages of all the phases changes to 0 (zero) V, and the neutral point detection voltage Vcom changes to a voltage corresponding to 0 (zero) V by the neutral point voltage detection circuit 5.

Specifically, when the motor is idling, due to the rotation of the rotor relative to the coils, an induced voltage (eu, ev, ew) proportional to the rotational speed is generated in each phase of coil, with polarity in a direction of generating a current preventing a change in magnetic flux, in an electric angle period of the motor rotation with each phase shifted by 120 degrees. At this time, the current waveform has a phase delayed by 90 degrees with respect to the voltage waveform. However, this voltage waveform is not detected as the neutral point detection voltage Vcom.

### Discharge Mode

Next, the control electrodes (gate electrodes) of the respective switching elements Q1 to Q6 of the inverter circuit 2a are switched from the second switch state to the first switch state again by the idling control signal Id output from the control circuit 1. Specifically, for example, in the inverter circuit 2a, the second switch state where the switch states of the switching elements Q2, Q4, and Q6 of the lower arms among the respective switching elements Q1 to Q6 are on is switched again to the first switch state where all the switch states of the respective switching elements Q1 to Q6 are off, as illustrated in FIG. 4.

As illustrated in FIG. 4, in a case where the rotor of the motor 3 is idling, a path of the circulating induced current is interrupted in the inverter circuit 2a when the switch state changes from the second switch state to the first switch state. At this time, because the induced current (A in FIG. 4) been circulating through the coil (winding) of the motor 3 attempts to continue to flow through the coil, inductive kickback (B in FIG. 4) occurs in the inverter circuit 2a. Specifically, a voltage rise occurs at a connection point between the upper arm and the lower arm of the leg of the phase downstream of the induced current, and a voltage drop occurs at a connection point between the upper arm and the lower arm of the leg of the phase upstream of the induced current. Since this voltage fluctuation is clamped by parasitic diodes of the respective switching elements Q1 to Q6, when the number of phases of the motor is three, based on the DC power supply Vin and a forward voltage Vf of the parasitic diodes and depending on a rotor position, the phase voltage of a phase located most downstream side of the induced current rises to Vin + Vf, the phase voltage of a phase located most upstream side of the induced current falls to −Vf, and the phase voltages of remaining phases rise to Vin + Vf or fall to −Vf depending on a direction of the induced current. In addition, this voltage fluctuation occurs for a short time, and when the number of phases of the motor is three, depending on the rotor position, the voltage fluctuation time of a phase located most downstream side of the induced current and a phase located most upstream side of the induced current becomes the longest. At this time, in the neutral point voltage, a voltage fluctuation in a positive direction occurs due to the inductive kickback under the influence of the combining circuit and the parasitic diodes.

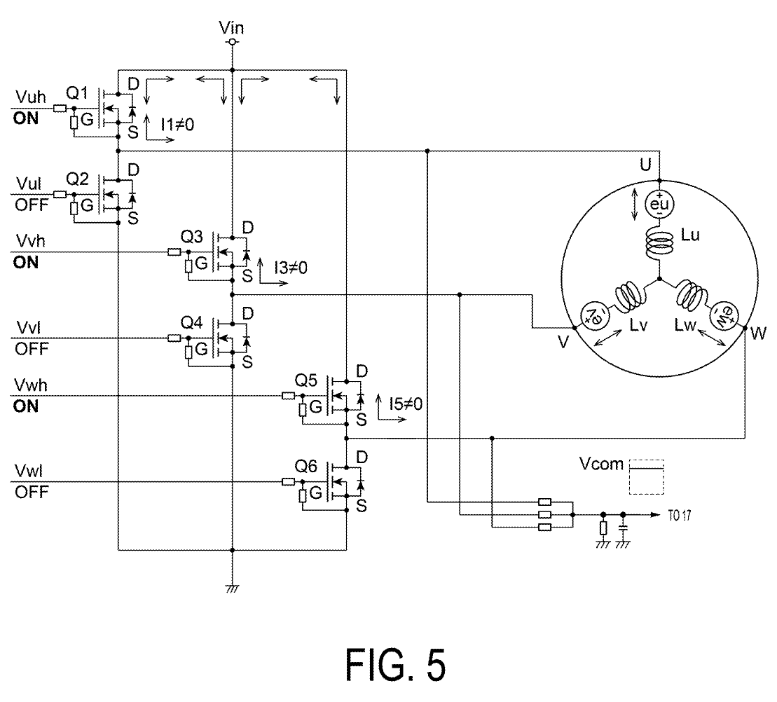

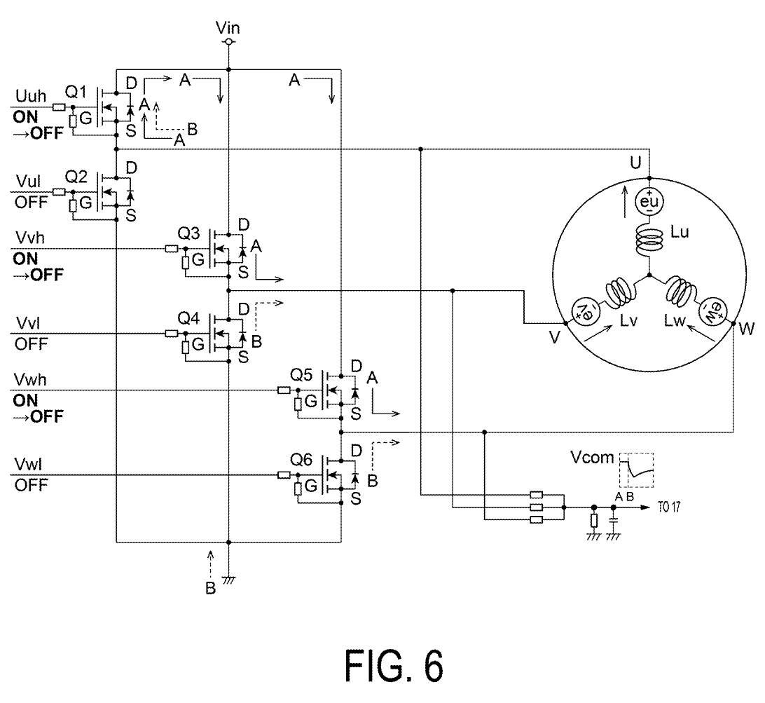

Next, a case where switching of the high-side switches is performed will be described. In FIGS. 5 and 6, during idling detection by switching of the high-side switches, states of currents flowing, when the motor 3 is idling, in the coils of the motor 3 and the inverter circuit 2a are indicated by arrows.

Even when switching of the high-side switches is performed, the idling control signal Id is a signal for switching to the corresponding switch states in the order of the free mode (FIG. 2), the charge mode (FIG. 5), and the discharge mode (FIG. ). Note that the states of the switches and the voltages generated the coils in the free mode illustrated in FIG. 2 are the same as those in the case where switching of the low-side switches is performed, and thus the description thereof will be omitted.

### Charge Mode

Next, the control electrodes (gate electrodes) of the respective switching elements Q1 to Q6 of the inverter circuit 2a are switched from the first switch state to the second switch state by the idling control signal Id output from the control circuit 1. The second switch state is a switch state where, when the rotor of the motor 3 is idling, an induced electromotive force is generated the coil of each phase, and the generated induced current circulates in a closed circuit formed by the coil and the switching element on among the switching elements Q1 to Q6. Specifically, in the inverter circuit 2a, the first switch state where all of the switch states of the respective switching elements Q1 to Q6 are off is switched to the second switch state where the switch states of only the switching elements Q1, Q3, and Q5 of the upper arms among the respective switching elements Q1 to Q6 are on, for example, as illustrated in FIG. 5.

As illustrated in FIG. 5, in the inverter circuit 2a, once the second switch state is reached turning on the switch states of the switching elements Q1, Q3, and Q5 of the upper arms among the switching elements Q1 to Q6, when the rotor of the motor 3 is idling, induced currents circulating between the coils of the motor 3 and the inverter circuit 2a are generated the coils of respective phases, and the generated induced currents circulate in the closed circuit formed by the coils and the switching elements Q1, Q3, and Q5 of the upper arms on. At this time, the phase voltage of each phase is not affected by the induced voltage because the switching element of the upper arm is on, and thus changes to the power supply voltage Vin. The neutral point voltage obtained by combining the phase voltages of all the phases changes to the power supply voltage Vin, and the neutral point detection voltage Vcom changes to a voltage corresponding to the power supply voltage Vin by the neutral point voltage detection circuit 5.

Specifically, when the motor is idling, due to the rotation of the rotor relative to the coils, an induced voltage (eu, ev, ew) proportional to the rotational speed is generated in each phase of coil, with polarity in a direction of generating a current preventing a change in magnetic flux, in an electric angle period of the motor rotation with each phase shifted by 120 degrees. At this time, the current waveform has a phase delayed by 90 degrees with respect to the voltage waveform. However, this voltage waveform is not detected as the neutral point detection voltage Vcom.

### Discharge Mode

Next, the control electrodes (gate electrodes) of the respective switching elements Q1 to Q6 of the inverter circuit 2a are switched from the second switch state to the first switch state again by the idling control signal Id output from the control circuit 1. Specifically, for example, in the inverter circuit 2a, the second switch state where the switch states of the switching elements Q1, Q3, and Q5 of the upper arms among the respective switching elements Q1 to Q6 are on is switched again to the first switch state where all the switch states of the respective switching elements Q1 to Q6 are off, as illustrated in FIG. 6.

As illustrated in FIG. 6, in a case where the rotor of the motor 3 is idling, the path of the circulating induced current is interrupted in the inverter circuit 2a when the switch state changes from the second switch state to the first switch state. At this time, because the induced current (A in FIG. 6) circulating through the coil (winding) of the motor 3 attempts to continue to flow through the coil, inductive kickback (B in FIG. 6) occurs in the inverter circuit 2a. Specifically, a voltage rise occurs at a connection point between the upper arm and the lower arm of the leg of the phase downstream of the induced current, and a voltage drop occurs at a connection point between the upper arm and the lower arm of the leg of the phase upstream of the induced current. Since this voltage fluctuation is clamped by parasitic diodes of the respective switching elements Q1 to Q6, when the number of phases of the motor is three, based on the DC power supply Vin and a forward voltage Vf of the parasitic diodes and depending on a rotor position, the phase voltage of a phase located most downstream side of the induced current rises to Vin + Vf, the phase voltage of a phase located most upstream side of the induced current falls to −Vf, and the phase voltages of remaining phases rise to Vin + Vf or fall to −Vf depending on a direction of the induced current. In addition, this voltage fluctuation occurs for a short time, and when the number of phases of the motor is three, depending on the rotor position, the voltage fluctuation time of a phase located most downstream side of the induced current and a phase located most upstream side of the induced current becomes the longest. At this time, in the neutral point voltage, a voltage fluctuation in a negative direction occurs due to the inductive kickback under the influence of the combining circuit and the parasitic diodes.

In the motor drive control device 10 of the present embodiment, when the voltage generated the neutral point voltage detection circuit 5 is detected and the voltage fluctuation due to the inductive kickback is determined to have occurred, the motor 3 can be determined to be idling.

The idling control signal Id is a signal for switching each of the switching elements constituting the inverter circuit 2a to switch states corresponding to the three modes for detecting the idling of the motor 3. The idling control signal Id is different from the drive control signal Sd for driving the motor, and is not a signal for generating a drive voltage in the coils of the motor 3, so the idling control signal Id is not a signal for alternately switching on and off states of each of the switching elements, but a high or low signal having a predetermined length, for example. The idling control signal Id includes six types of signals corresponding to the respective switching elements Q1 to Q6 of the inverter circuit 2a.

Based on the idling control signal Id output from the control circuit 1, the pre-drive circuit 2b generates a drive signal as a switching signal for switching the switch state of each of the switching elements constituting the inverter circuit 2a.

Based on the six types of signals as the idling control signal Id supplied from the control circuit 1, the pre-drive circuit 2b generates a signal capable of supplying sufficient power to switch the switch states of the control electrodes (gate electrodes) of the respective switching elements Q1 to Q6 of the inverter circuit 2a. As these switching signals, the drive signals are input to the control electrodes (gate electrodes) of the respective switching elements Q1 to Q6 of the inverter circuit 2a, thereby switching the switch states of the respective switching elements Q1 to Q6. Details of the idling control signal Id will be described below.

In the embodiment, the control circuit 1 is a program processing device (e.g., a microcontroller) having a configuration. In the configuration, for example, a processor such as a CPU, various storage devices such as a RAM and a ROM, and peripheral circuits such as a counter (timer), an A/D conversion circuit, a D/A conversion circuit, a clock generation circuit, and an input/output I/F circuit are connected to each other via a bus or a dedicated line.

Note that the motor drive control device 10 may have a configuration. In the configuration, at least a part of the control circuit 1 and at least a part of the drive circuit 2 are packaged as one integrated circuit device (IC), or the control circuit 1 and the drive circuit 2 are separately packaged as individual integrated circuit devices.

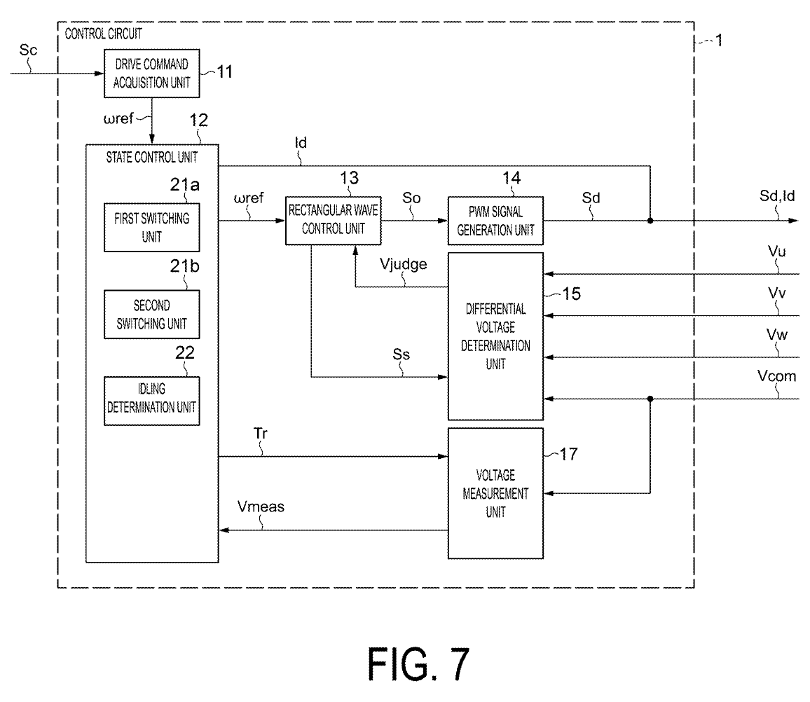

FIG. 7 is a diagram illustrating a functional block configuration of the control circuit 1 in the motor drive control device 10 according to the embodiment.

As illustrated in FIG. 7, the control circuit 1 includes, for example, a drive command acquisition unit 11, a state control unit 12, a rectangular wave control unit 13, a PWM signal generation unit 14, and a differential voltage determination unit 15, as functional blocks for generating the drive control signal Sd in driving the motor by a 120-degree energization rectangular wave drive method. In addition, the control circuit 1 includes the state control unit 12 and a voltage measurement unit 17, as functional blocks for generating the idling control signal Id in idling detection of the motor. The state control unit 12 includes a first switching unit 21a, a second switching unit 21b, and an idling determination unit 22.

These functional blocks are implemented, for example, in a program processing device as the control circuit 1, by the processor executing various arithmetic operations according to a program stored in a memory and controlling peripheral circuits such as a counter and an A/D conversion circuit.

The drive command acquisition unit 11 receives the speed command signal Sc from the outside and analyzes the received speed command signal Sc to acquire a value specifying a target operation state of the motor 3 specified by the speed command signal Sc.

The speed command signal Sc includes a value indicating a target operation state of the motor 3. The speed command signal Sc is a signal output from a ost device for controlling the motor unit 100 provided outside the motor drive control device 10, for example.

In the embodiment, the speed command signal Sc specifies, for example, the rotational speed of the rotor of the motor 3. The speed command signal Sc includes a value ωref of the rotational speed as a target (target rotational speed) of the rotor of the motor 3.

The speed command signal Sc is, for example, a PWM signal having a duty ratio corresponding to a specified target rotational speed ωref. The drive command acquisition unit 11, for example, measures the duty ratio of the PWM signal of the speed command signal Sc, and outputs the rotational speed corresponding to the measured duty ratio as the target rotational speed ωref.

In driving the motor, the state control unit 12 outputs the target rotational speed ωref as it is to the rectangular wave control unit 13. The state control unit 12 can determine how to start the motor when an idling determination signal described below is generated from the idling determination unit 22. Note that although not specifically illustrated in FIG. 7, the state control unit 12 may further include a function unit for executing such processing.

The state control unit 12 outputs a measurement trigger signal Tr to the voltage measurement unit 17 in idling detection of the motor. The measurement trigger signal Tr is a signal for triggering the measurement in the voltage measurement unit 17, and for example, a signal for turning on and off a sampling circuit 172 within the voltage measurement unit 17 described below.

In driving the motor, the rectangular wave control unit 13 outputs a drive command signal So to the PWM signal generation unit 14 and outputs a differential voltage selection signal Ss to the differential voltage determination unit 15. The differential voltage selection signal Ss is a signal for selecting a phase to be detected by the differential voltage determination unit 15 among the coil phases of the motor.

In driving the motor, in order to acquire switching timings of six energization directions in a drive control method using a 120-degree rectangular wave, the rectangular wave control unit 13 outputs the differential voltage selection signal Ss corresponding to a non-energization phase (induced voltage phase) to the differential voltage determination unit 15, receives a voltage determination signal Vjudge indicating a zero-cross timing a differential voltage between the induced voltage of the selected non-energization phase and the neutral point voltage becom zero, and adjusts energization switching in drive control. The differential voltage determination unit 15 detects the differential voltage between the induced voltage (phase voltage) of the non-energization phase selected by the differential voltage selection signal Ss and the neutral point voltage, thereby outputting a signal indicating the zero-cross timing as the voltage determination signal Vjudge.

The rectangular wave control unit 13, in driving the motor, generates the drive command signal So from the target rotational speed ωref and the voltage determination signal Vjudge in accordance with the drive control method using a 120-degree rectangular wave, and outputs the generated drive command signal So to the PWM signal generation unit 14 to perform drive control of the motor. The voltage determination signal Vjudge is a signal indicating the zero-cross timing determined by the voltage determination unit 15. The rectangular wave control unit 13 performs drive control of the motor by, for example, energizing the windings from the U-phase to the V-phase by one-phase excitation, and performing energization switching by using the zero-cross timing obtained by detecting the differential voltage between the induced voltage (phase voltage) generated in the W-phase of the non-energization phase and the neutral point voltage.

In driving the motor, the PWM signal generation unit 14 generates the drive control signal Sd in accordance with the drive command signal So received from the rectangular wave control unit 13, and outputs the drive control signal Sd to the drive circuit 2, thereby performing PWM control of the drive circuit 2.

The differential voltage determination unit 15 is configured to detect the differential voltage between the induced voltage (phase voltage) of the non-energization phase selected by the differential voltage selection signal Ss and the neutral point voltage, thereby outputting a signal indicating the zero-cross timing the differential voltage chang, as the voltage determination signal Vjudge.

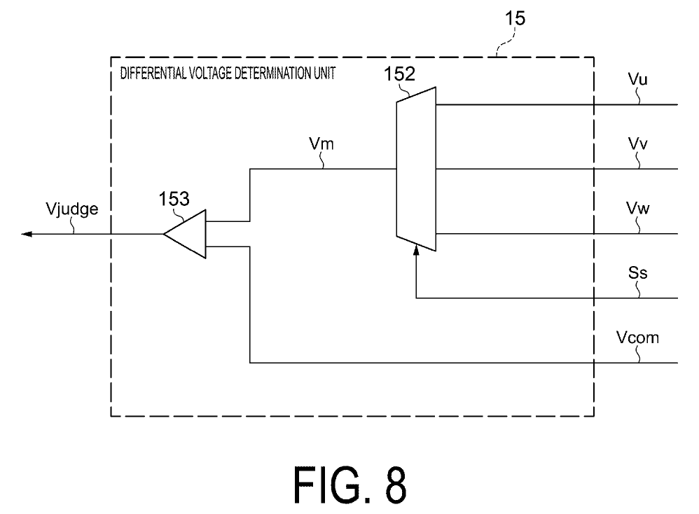

FIG. 8 is a diagram illustrating an example of a configuration of the differential voltage determination unit 15. Here, the example of the configuration of the differential voltage determination unit 15 will be described.

The differential voltage determination unit 15 receives the phase detection voltages Vu, Vv, and Vw of the respective phases, the differential voltage selection signal Ss, and the neutral point detection voltage Vcom, and outputs the differential voltage determination signal Vjudge. The differential voltage determination unit 15 includes a measurement phase selection multiplexer (MUX) 152 and a comparator 153. The differential voltage determination unit 15 inputs the phase detection voltages Vu, Vv, and Vw of the respective phases to the measurement phase selection multiplexer 152, and controls an operation of the measurement phase selection multiplexer 152 by the differential voltage selection signal Ss. The measurement phase selection multiplexer (MUX) 152 inputs a phase detection voltage Vm of a phase selected by the differential voltage selection signal Ss to the comparator 153. To the comparator 153, the phase detection voltage Vm output from the measurement phase selection multiplexer 152 and the neutral point detection voltage Vcom are input, and when a voltage difference Vm-Vcom is equal to or greater than a hysteresis near 0 (zero) V, the voltage determination signal Vjudge, as an output and as a rising zero cross, becomes a control voltage Vdc. On the other hand, when the voltage difference Vm-Vcom is less than the hysteresis, the voltage determination signal Vjudge, as an output and as a falling zero cross, becomes 0 (zero) V.

The voltage measurement unit 17 is an A/D converter digitiz a voltage of an input signal, and is configured to output, to the state control unit 12, a neutral point voltage measurement value Vmeas corresponding to the neutral point detection voltage Vcom input from the neutral point voltage detection circuit 5 in idling detection of the motor.

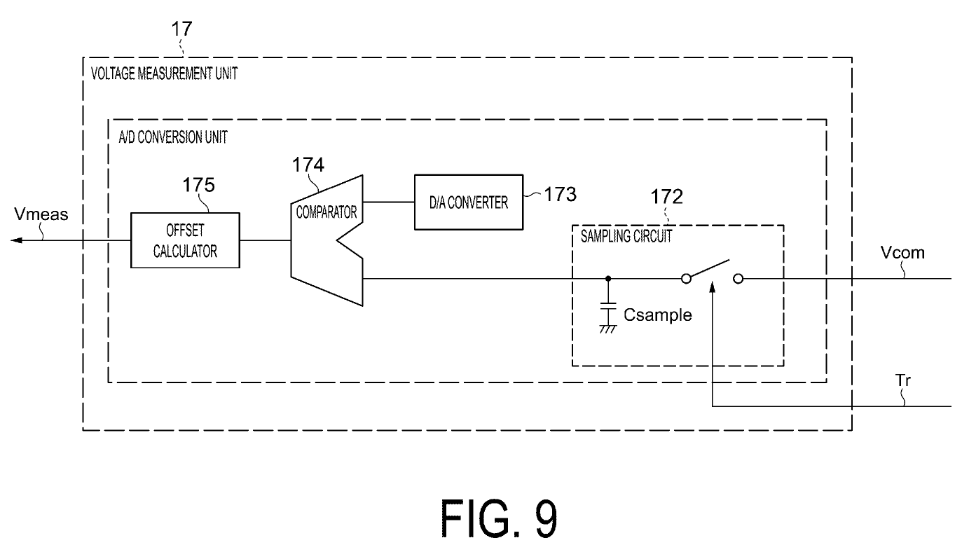

FIG. 9 is a diagram illustrating an example of a configuration of the voltage measurement unit 17. Here, the example of the configuration of the voltage measurement unit 17 will be described. As illustrated in FIG. 9, for example, the voltage measurement unit 17 includes a sampling circuit 172, a D/A converter 173, a comparator 174, and an offset calculator 175.

In idling detection of the motor, the voltage measurement unit 17 measures the neutral point voltage measurement value Vmeas corresponding to the neutral point detection voltage Vcom in accordance with the measurement trigger signal Tr input from the state control unit 12.

The idling determination controlled by the state control unit 12 will now be described further.

In the state control unit 12, during idling detection of the motor, the first switching unit 21a generates the idling control signal Id for switching to the first switch state, the second switching unit 21b generates the idling control signal Id for switching to the second switch state, and the idling control signal Id is output to the drive circuit 2. The start of the generation of the idling control signal Id can be triggered by reception of the speed command signal Sc after power-on, or after motor stop (after elapse of a predetermined time from interruption of the speed command signal Sc).

In the state control unit 12, the first switching unit 21a generates the idling control signal Id switching the switching elements Q1 to Q6 constituting the inverter circuit 2a to the first switch state. In the state control unit 12, the second switching unit 21b generates the idling control signal Id switching the switching elements Q1 to Q6 constituting the inverter circuit 2a to the second switch state. The idling control signal Id generated by the first switching unit 21a and the second switching unit 21b of the state control unit 12 is output to the drive circuit 2.

In the state control unit 12, to set a switch state enabling the idling detection of the motor, after power-on and until the speed command signal Sc is received by the drive command acquisition unit 11, the idling control signal Id corresponding to the free mode is generated by the first switching unit 21a, and start of driving of the motor is awaited. Thereafter, in the state control unit 12, to detect the presence or absence of an idling state immediately before driving the motor by the input of the speed command signal Sc, the idling control signal Id is generated by the second switching unit 21b during a charging time (a period corresponding to the charge mode). Further thereafter, in the state control unit 12, the idling control signal Id is generated again by the first switching unit 21a during a discharging time (a period corresponding to the discharge mode). Note that, after the discharging time, the idling control signal Id corresponding to the free mode may be generated again by the first switching unit 21a. In addition, in order to detect again the presence or absence of the idling state of the motor, the state control unit 12 may execute the charge mode and the discharge mode again immediately after transition to the free mode or after elapse of a predetermined waiting time.

The transition timing from the free mode to the charge mode may be after the drive command acquisition unit 11 has received the speed command signal Sc, for example.

In idling detection of the motor, the state control unit 12 instructs the voltage measurement unit 17 to measure the input neutral point detection voltage Vcom by outputting the measurement trigger signal Tr for idling detection turn on a switch of the sampling circuit 172, at a timing immediately before transition from the charge mode to the discharge mode, i.e., in a state the neutral point voltage is constant immediately before switching from the second switch state to the first switch state. Based on the instruction from the state control unit 12, the voltage measurement unit 17 performs A/D conversion on the input neutral point detection voltage Vcom to generate the neutral point voltage measurement value Vmeas. The voltage measurement unit 17 outputs the generated neutral point voltage measurement value Vmeas to the idling determination unit 22 of the state control unit 12. This neutral point voltage measurement value Vmeas is used as a reference voltage. After the measurement of the neutral point detection voltage Vcom, the mode transitions to the discharge mode.

In idling detection of the motor, the state control unit 12 instructs the voltage measurement unit 17 to measure the input neutral point detection voltage Vcom by outputting the measurement trigger signal Tr for idling detection turn on a switch of the sampling circuit 172 at a predetermined timing, in a discharge mode, that is, after switching from the second switch state to the first switch state and after elapse of a short mask time for avoiding an influence caused by switching of the switching elements. Based on the instruction from the state control unit 12, the voltage measurement unit 17 performs A/D conversion on the input neutral point detection voltage Vcom to generate the neutral point voltage measurement value Vmeas. The voltage measurement unit 17 outputs the generated neutral point voltage measurement value Vmeas to the idling determination unit 22 of the state control unit 12. This neutral point voltage measurement value Vmeas is used as a measured voltage. The measurement of the neutral point detection voltage Vcom is executed once during the period of the discharge mode.

The idling determination unit 22 determines whether the motor 3 is idling based on the neutral point voltage measurement value Vmeas generated by the voltage measurement unit 17, and generates an idling determination signal indicating an idling determination result. Specifically, the idling determination unit 22 uses, as a measured voltage, the voltage measurement value Vmeas obtained by instructing the voltage measurement unit 17 to perform measurement at a predetermined timing, calculates a fluctuation voltage difference a difference between the reference voltage and the measured voltage, compares the calculated fluctuation voltage difference with a preset threshold value (an idling threshold value), and determines the motor 3 when the fluctuation voltage difference is greater than the idling threshold value.

As the idling threshold value, a fluctuation voltage difference a difference between the reference voltage and the measured voltage of the neutral point voltage measurement value Vmeas at a minimum rotational speed idling detect (a minimum idling rotational speed) may be used.

As the charging time, a time measured in advance such that the voltage fluctuation difference at the minimum rotational speed idling (a minimum idling rotational speed) can be measured may be used, since the voltage fluctuation generated the neutral point voltage detection circuit 5 by the inductive kickback varies according to the rotational speed and the rotor position. As the charging time is shortened, the idling detection period is shortened, and the abnormal noise of the drive system caused by a short brake state during the charging time is reduced, is preferable.

As the discharging time, a previously measured time until a maximum voltage fluctuation converges at a maximum rotational speed idling detect (a maximum idling rotational speed) may be used, since the voltage fluctuation generated the neutral point voltage detection circuit 5 by the inductive kickback converges over time and returns to the free mode state before idling detection.

Next, the transition of the mode after power-on of the state control unit 12 will be described in detail.

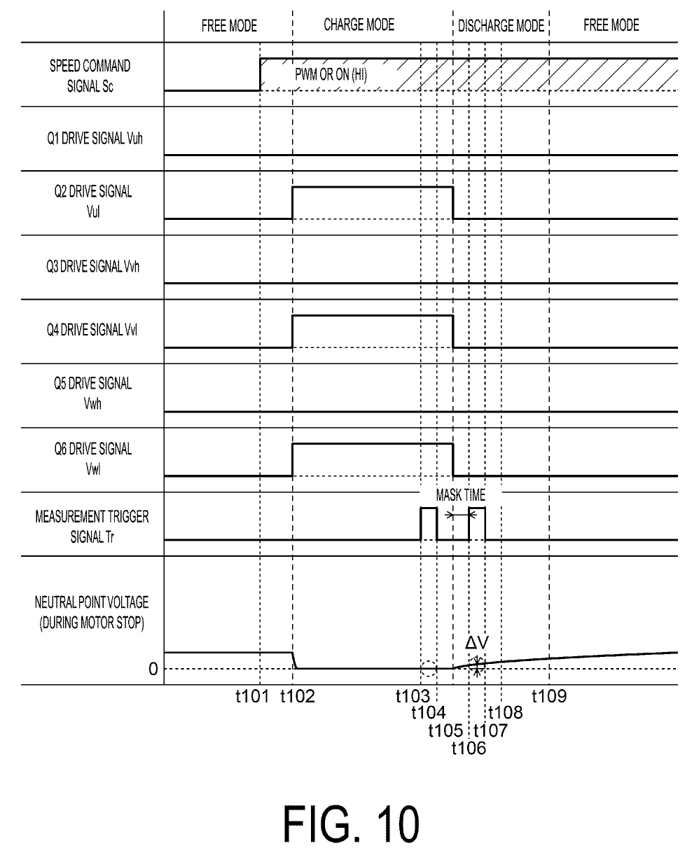

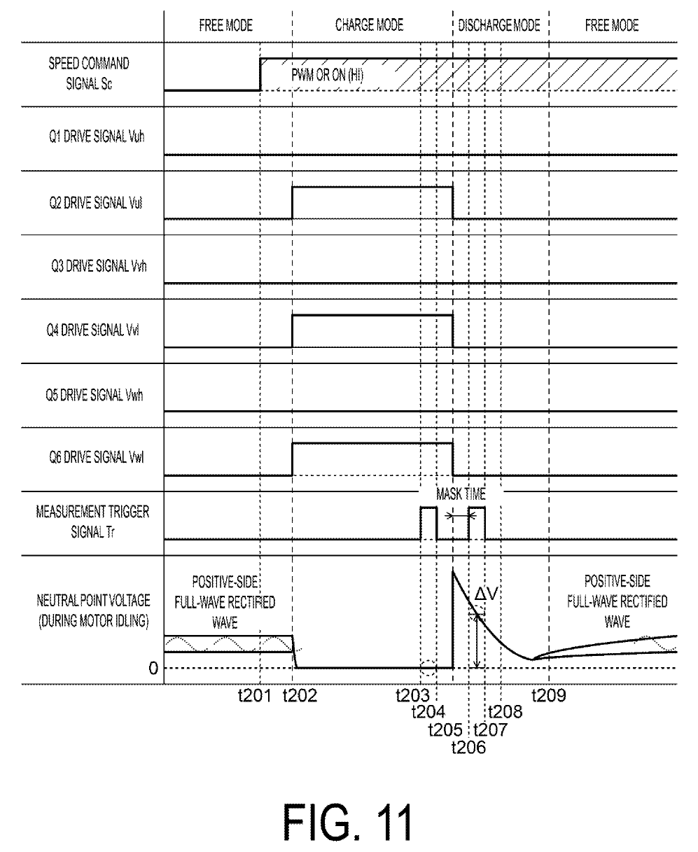

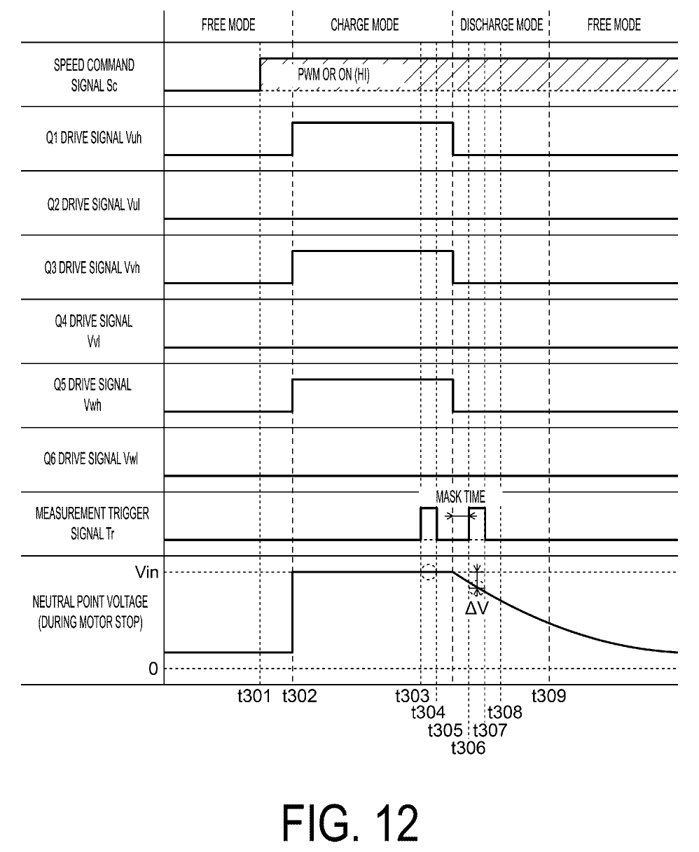

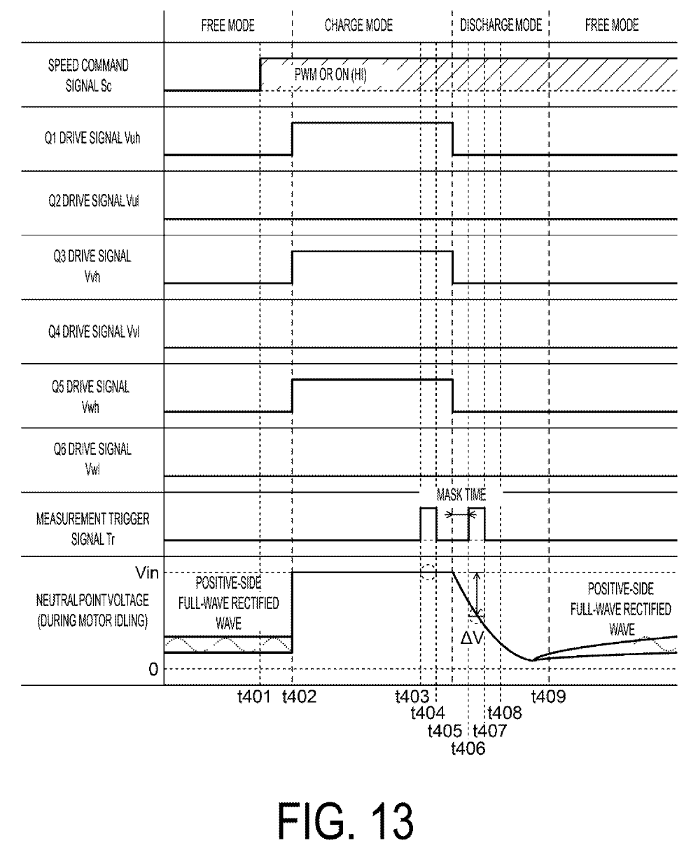

FIGS. 10 - 13 are timing charts illustrating an example of signal waveforms from power-on of the motor unit 100, through input of the speed command signal Sc, until completion of idling determination. FIGS. 10 and 11 are timing charts when the idling detection is performed by switching of the low-side switches. FIGS. 12 and 13 are timing charts when the idling detection is performed by switching of the high-side switches. FIGS. 10 and 12 illustrate waveforms in a motor stop state, and FIGS. 11 and 13 illustrate waveforms in a motor idling state.

In FIGS. 10 - 13, waveforms of the speed command signal Sc, the drive signals input to the gates of the switching elements Q1 to Q6, the measurement trigger signal Tr for idling detection, and the neutral point voltage are illustrated in order from the top.

The speed command signal Sc is a signal received as the target rotational speed ωref in the state control unit 12, and the state control unit 12, using reception of the speed command signal Sc as a trigger, generates the idling control signal Id including the respective drive signals input to the gates of switching elements Q1 to Q6 and the measurement trigger signal Tr for idling detection input to the voltage measurement unit 17, at a predetermined timing.

In the examples illustrated in FIGS. 1 and 13, the motor drive control device 10 is shown to sequentially transition through the free mode, the charge mode, and the discharge mode, and then to return to the free mode again. At this time, the motor drive control device 10 starts from the free mode after power-on. Note that the timing charts illustrated in FIGS. 10 - 13 illustrate, as an example, the mode to the free mode again after the discharge mode, but no such limitation is intended.

In the free mode, the inverter circuit 2a is set to the first switch state by the idling control signal Id. Specifically, in response to the idling control signal Id generated by the first switching unit 21a, all the drive signals input to the gates of switching elements Q1 to Q6 constituting the inverter circuit 2a are set to low, and all switches of the inverter circuit are turned off. In this state, the closed circuit is not constituted, so the winding current of the coil (winding) is 0 (zero) A, and no current flows.

In this state, as illustrated in FIGS. 11 and 13, when the rotor of the motor 3 is idling, an induced electromotive force is generated the coils of the motor 3, and an induced voltage is periodically generated in the phase voltage of each phase. (Positive-side saddle wave) At this time, the neutral point voltage obtained by combining the phase voltages of all the phases is clamped by the parasitic diodes due to all the switching elements Q1 to Q6 being turned off, and thus oscillates as a positive-side full-wave rectified wave having an amplitude determined by the induced voltage corresponding to the idling rotational speed and a period of three times a period of the phase voltage.

In this state, as illustrated in FIGS. 10 and 12, when the rotor of the motor 3 is stopped, no induced electromotive force is generated the coils of the motor 3, and thus the neutral point voltage obtained by combining the phase voltages of all the phases changes to 0 (zero) V due to all the switching elements Q1 to Q6 being turned off. At this time, when an N-channel MOSFET is used at the HI side of the inverter circuit, a voltage applied by a circuit for boosting the gate voltage to be higher than the source voltage in order to turn on the FET may appear, and this voltage is illustrated in FIGS. 10 and 12.

Next, in the charge mode, the inverter circuit 2a is set to the second switch state by the idling control signal Id. Specifically, by the idling control signal Id generated by the second switching unit 21b, all the drive signals input to the gates of the switching elements Q2, Q4, and Q6 of the lower arms or the switching elements Q1, Q3, and Q5 of the upper arms among the switching elements Q1 to Q6 constituting the inverter circuit 2a are set to high, and all the low-side switches (FIGS. 10 and 11) or all the high-side switches (FIGS. 12 and 13) of the inverter circuit are turned on.

In this state, when the rotor of the motor 3 is idling, induced electromotive forces are generated the coils of the motor 3, so that, as illustrated in FIGS. 3 and 5, a closed circuit is formed by the coils of the motor 3 and the switching elements Q2, Q4, and Q6 (FIG. 3) or the switching elements Q1, Q3, and Q5 (FIG. 5) turned on in the inverter circuit 2a, and induced currents circulating between the coils of the motor 3 and the inverter circuit 2a are generated.

In the charge mode, as illustrated in FIG. 3, when switching is performed by the switching elements Q2, Q4, and Q6 of the lower arms, the phase voltage of each phase changes to 0 (zero) V due to all the LO-side switching elements Q2, Q4, and Q6 being turned on, regardless of whether the motor is in the stop state (FIG. 10) or the idling state (FIG. 11). The neutral point voltage also changes to 0 (zero) V due to all the LO-side switching elements Q2, Q4, and Q6 being turned on.

In the charge mode, as illustrated in FIG. , when switching is performed by the switching elements Q1, Q3, and Q5 of the upper arms, the phase voltage of each phase changes to the power supply voltage Vin due to all the HI-side switching elements Q1, Q3, and Q5 being turned on, regardless of whether the motor is in the stop state (FIG. 12) or the idling state (FIG. 1). The neutral point voltage obtained by combining the phase voltages of all the phases also changes to the power supply voltage Vin due to all the HI-side switching elements Q1, Q3, and Q5 being turned on.

Before the duration of the charge mode expires, in any of FIGS. 10 - 13, in the state control unit 12, the neutral point detection voltage Vcom is measured by the measurement trigger signal Tr and is set as the reference voltage. As illustrated in FIG. 3, when switching is performed by the switching elements Q2, Q4, and Q6 of the lower arms, a voltage corresponding to 0 (zero) V is measured, and as illustrated in FIG. 5, when switching is performed by the switching elements Q1, Q3, and Q5 of the upper arms, a voltage corresponding to the power supply voltage Vin is measured.

Next, in the discharge mode, the inverter circuit 2a is again set to the first switch state by the idling control signal Id. Specifically, due to the idling control signal Id generated by the first switching unit 21a, all the drive signals input to the gates of the switching elements Q1 to Q6 constituting the inverter circuit 2a are again set to low, and all the switches of the inverter circuit are turned off.

In this state, when the rotor of the motor 3 is idling, the induced currents circulating between the coils of the motor 3 and the inverter circuit 2a during the charge mode attempt to continue to flow through the coils, so the inductive kickback occurs in the inverter circuit 2a due to all the switching elements Q1 to Q6 being turned off.

In the discharge mode, the influence of the induc kickback generated the inverter circuit 2a on the neutral point voltage is different between the case where switching is performed by the switching elements Q2, Q4, and Q6 of the lower arms as illustrated in FIGS. 3 (FIG. 11) and the case where switching is performed by the switching elements Q1, Q3, and Q5 of the upper arms as illustrated in FIGS. 5 (FIG. 13) .

As illustrated in FIG. 3, when switching is performed by the switching elements Q2, Q4, and Q6 of the lower arms (FIG. 11), due to the inductive kickback generated the 2a, a voltage fluctuation in a positive direction also occurs in the neutral point voltage due to the inductive kickback. At this time, as the neutral point detection voltage Vcom measured by the measurement trigger signal Tr in the discharge mode, a voltage including the voltage fluctuation in the positive direction caused by the inductive kickback is measured. Note that when the rotor of the motor 3 is stopped, the state returns to the state of the free mode before the idling detection without the occurrence of the inductive kickback (FIG. 10).

As illustrated in FIG. 5, when switching is performed by the switching elements Q1, Q3, and Q5 of the upper arms (FIG. 13), due to the inductive kickback generated the 2a, a voltage fluctuation in a negative direction also occurs in the neutral point voltage due to the inductive kickback. At this time, as the neutral point detection voltage Vcom measured by the measurement trigger signal Tr in the discharge mode, a voltage including the voltage fluctuation in the negative direction caused by the inductive kickback is measured. Note that when the rotor of the motor 3 is stopped, the state returns to the state of the free mode before the idling detection without the occurrence of the inductive kickback (FIG. 12).

It is understood that the voltage corresponding to the difference ΔV between the reference voltage the neutral point detection voltage Vcom measured in the charge mode, and the measured voltage the neutral point detection voltage Vcom measured in the discharge mode, is clearly different between the case the inductive kickback occur due to the motor being idling (FIGS. 11 and 13) and the case the inductive kickback not occur due to the motor being stopped (FIGS. 10 and 12). In the present embodiment, when the voltage corresponding to the difference ΔV is larger than a predetermined idling threshold value, the motor is in an idling state.

After elapse of time from the measurement in the discharge mode, the neutral point voltage converges as the influence of inductive kickback is eliminated, and the coil of the motor and the inverter circuit do not form a closed circuit due to the discharge mode, so the influence of the induced voltage due to the idling of the motor appears, and the neutral point voltage returns to the oscillation having a waveform similar to the waveform in the state of the free mode before idling detection.

After the discharge mode, the free mode may come back again. In the free mode after the discharge mode, the inverter circuit 2a is set to the first switch state by the idling control signal Id. Specifically, in response to the idling control signal Id generated by the first switching unit 21a, all the drive signals input to the gates of the switching elements Q1 to Q6 constituting the inverter circuit 2a are set to low, and all switches of the inverter circuit are turned off. In this state, the closed circuit is not formed, so the winding current of the coil (winding) is 0 (zero) A, and no current flows.

In the free mode again, the neutral point voltage is clamped by the parasitic diodes due to all the switching elements Q1 to Q6 being turned off, and thus returns to the oscillation as a positive-side full-wave rectified wave having an amplitude determined by the induced voltage corresponding to the idling rotational speed and a period of three times a period of the phase voltage, while the voltage fluctuation due to the inductive kickback converges.

The idling determination unit 22 receives the neutral point voltage measurement value Vmeas corresponding to the neutral point detection voltage Vcom described above from the voltage measurement unit 17. As described above, the idling determination unit 22 measures the neutral point voltage measurement value Vmeas once during the charge mode and once during the discharge mode, and performs the idling determination based on the difference between the neutral point voltage measurement value Vmeas during the discharge mode and the neutral point voltage measurement value Vmeas during the charge mode, used as the reference voltage.

During the predetermined discharging time, the state control unit 12 performs the measurement of the neutral point voltage measurement value Vmeas once after the elapse of the predetermined mask time. For example, idling determination may be performed by using, as the reference voltage, a neutral point voltage measurement value Vmeas measured in advance in the charge mode, using, as the measured voltage, a neutral point voltage measurement value Vmeas measured in the discharge mode, and comparing a difference between the reference voltage and the measured voltage with a preset idling threshold value. The idling determination unit 22 may determine the motor 3 when the difference between the reference voltage and the measured voltage exceeds the preset idling threshold value. The idling threshold value may be a value such that the difference between the reference voltage and the measured voltage of the neutral point voltage measurement value Vmeas can be determined at the minimum idling rotational speed idling detect

Next, the flow of each processing in idling detection by the control circuit 1 of the motor drive control device 10 according to an embodiment will be described.

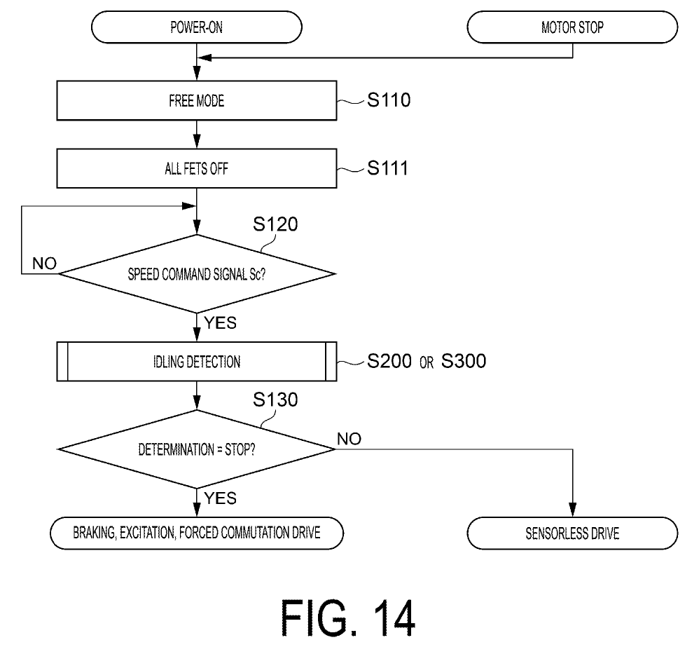

FIG. 14 is a flowchart illustrating an example of the flow of processing upon power-on in the control circuit 1 of the motor drive control device 10 according to the embodiment.

First, when the power is supplied to the motor drive control device 10, as illustrated in FIG. 14, if switching to the free mode is determined in the state control unit 12 (step S110), the first switching unit 21a generates the idling control signal Id for switching to the first switch state (all the switching elements Q1 to Q6 off) in order to set the switching elements Q1 to Q6 constituting the inverter circuit 2a to a switch state corresponding to the free mode (step S111).

The state control unit 12 generates the idling control signal Id for switching the switching elements Q1 to Q6 constituting the inverter circuit 2a to the first switch state according to the idling control signal Id generated in step S111. According to this idling control signal Id, the switching elements Q1 to Q6 constituting the inverter circuit 2a enter the first switch state illustrated in FIG. 2.

Thereafter, after power-on or after the motor stops, the state control unit 12 determines whether the speed command signal Sc has been received in the drive command acquisition unit 11 in order to wait for start of driving of the motor (step S120). The state control unit 12 repeats the determination until the speed command signal Sc is received in the drive command acquisition unit 11.

the drive command acquisition unit 11 receives the speed command signal Sc from the host device (step S120: YES), the state control unit 12 executes idling detection in order to detect the presence or absence of the idling state immediately before driving the motor (step S200 or step S300).

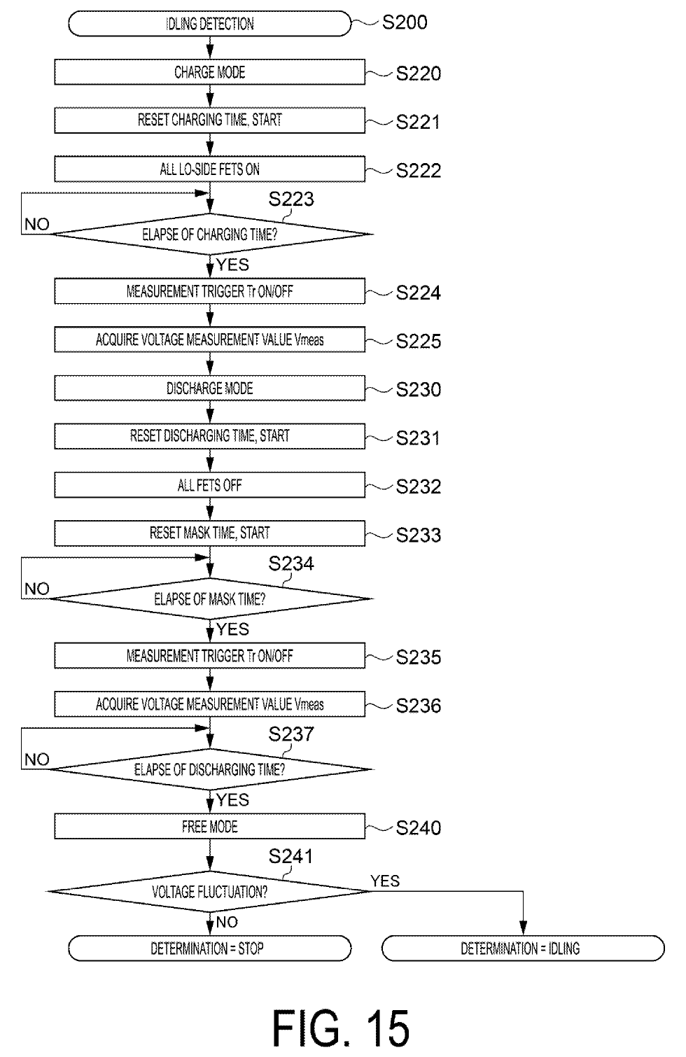

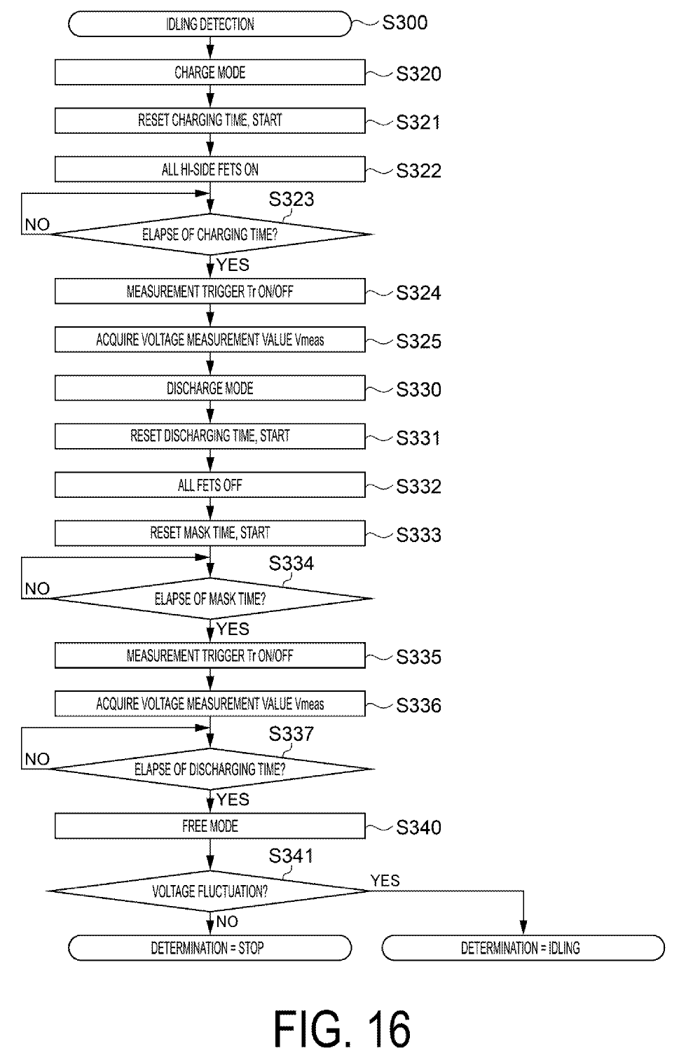

FIGS. 15 and 16 are flowcharts illustrating an example of the flow of idling detection processing by the control circuit 1 of the motor drive control device 10. FIG. 15 is a flowchart when switching of the low-side switches is performed, and FIG. 16 is a flowchart when switching of the high-side switches is performed.

First, the idling detection when switching of the low-side switches is performed will be described with reference to FIG. 15.

When the idling detection in step S200 is started, since the switch state is already the first switch state corresponding to the free mode, the state control unit 12 transitions to the charge mode (step S220).

When the charge mode is entered, a charging time of a charge timer is reset and counting of a new charging time is started in the state control unit 12 (step S221).

The state control unit 12 generates the idling control signal Id for switching the switching elements Q1 to Q6 constituting the inverter circuit 2a to the second switch state according to the idling control signal Id generated in step S220. In response to the idling control signal Id, the switching elements Q1 to Q6 constituting the inverter circuit 2a enter the second switch state the low-side switches Q2, Q4, and Q6 turned on, as illustrated in FIG. 3, for example (step S222).

The state control unit 12 determines whether a predetermined charging time has elapsed after the idling control signal Id is generated in step S220 (step S223).

When the predetermined charging time has elapsed after the idling control signal Id is generated (step S223: Yes), the state control unit 12 generates the measurement trigger signal Tr (step S224) in order to cause the voltage measurement unit 17 to measure the neutral point voltage measurement value Vmeas as a reference voltage serv as a reference with the neutral point voltage being in a constant state, and the voltage measurement unit 17 to measure the neutral point voltage measurement value Vmeas. The idling determination unit 22 acquires the neutral point voltage measurement value Vmeas obtained in step S224 as a reference voltage (step S225). At this time, in the voltage measurement unit 17, since a time (measurement time) from the measurement trigger Tr until completion of the measurement is short, the measurement is performed by turning on the measurement trigger Tr after elapse of the charging time. However, in this flowchart, for ease of explanation, a time from the start of the charge mode to the output of the measurement trigger signal is set as the charging time (S220 to S224). That is, the charging time in this flowchart is equal to or longer than a time measured in advance until the neutral point voltage after the transition to the charge mode becomes constant, and is equal to or shorter than a time obtained by subtracting the measurement time (S224 to S225) from the period (S220 to S225) the charge mode. Instead of the charging time, a trigger time may be used. When the trigger time is used, a trigger timer operat in parallel with the charge timer may be prepared in the state control unit 12, and the measurement trigger Tr may be turned on after the trigger time has elapsed. The trigger time is equal to or longer than a time measured in advance until the neutral point voltage after the transition to the charge mode becomes constant, and is equal to or shorter than a time obtained by subtracting the measurement time from the period the charge mode.

The state control unit 12 then transitions to the discharge mode (step S230). At this time, a discharging time of a discharge timer is reset and counting of a new discharging time is started in the state control unit 12 (step S231).

When the state control unit 12 generates the idling control signal Id in step S230, the switching elements Q1 to Q6 constituting the inverter circuit 2a are switched to the first switch state (step S232). That is, in response to the idling control signal Id, the switching elements Q1 to Q6 constituting the inverter circuit 2a enter again the first switch state, as illustrated in FIG. 4, for example. At this time, when the motor is idling, inductive kickback occurs in the inverter circuit. At this time, a mask time of a mask timer is reset and counting of a new mask time is started in the state control unit 12 (step S233).

The state control unit 12 determines whether a predetermined mask time has elapsed (step S234). When the predetermined mask time has elapsed (step S234: Yes), the state control unit 12 generates the measurement trigger signal Tr in order to cause the voltage measurement unit 17 to measure the neutral point voltage measurement value Vmeas because voltage fluctuation due to the inductive kickback occurs when the motor is idling, and causes the voltage measurement unit 17 to measure the neutral point voltage measurement value Vmeas (step S235). The idling determination unit 22 sets the neutral point voltage measurement value Vmeas obtained in step S235 as the measured voltage (step S236).

The state control unit 12 determines whether a predetermined discharging time has elapsed (step S237). When the predetermined discharging time has elapsed (step S237: Yes), the state control unit 12 enters the free mode (step S240).

After step S240, the idling determination unit 22 determines whether there is a voltage fluctuation based on the difference between the reference voltage acquired in step S225 and the measured voltage acquired in step S236 (step S241). The idling determination unit 22 can determine the motor 3 by determining a voltage fluctuation when the difference between the reference voltage acquired in step S225 and the measured voltage acquired in step S236 is larger than a predetermined idling threshold value.

When a voltage fluctuation (step S241: YES), the idling determination unit 22 determines the motor 3.

On the other hand, when no voltage fluctuation (step S241: NO), the idling determination unit 22 determines the motor 3 (not idling). The idling determination unit 22 generates an idling determination signal indicating the idling determination result. The idling determination signal is used by the state control unit 12.

Next, the idling detection when switching of the high-side switches is performed will be described with reference to FIG. 16.

When the idling detection in step S300 is started, since the switch state is already the first switch state corresponding to the free mode, the state control unit 12 transitions to the charge mode (step S320).

When the charge mode is entered, the charging time of the charge timer is reset and counting of a new charging time is started in the state control unit 12 (step S321).

The state control unit 12 generates the idling control signal Id for switching the switching elements Q1 to Q6 constituting the inverter circuit 2a to the second switch state according to the idling control signal Id generated in step S320. In response to the idling control signal Id, the switching elements Q1 to Q6 constituting the inverter circuit 2a enter the second switch state all the high-side switches Q1, Q3, and Q5 turned on, as illustrated in FIG. 5, for example (step S322).

The state control unit 12 determines whether a predetermined charging time has elapsed after the idling control signal Id is generated in step S320 (step S323).

When the predetermined charging time has elapsed after the idling control signal Id is generated (step S323: Yes), the state control unit 12 generates the measurement trigger signal Tr (step S324) in order to cause the voltage measurement unit 17 to measure the neutral point voltage measurement value Vmeas as a reference voltage serv as a reference with the neutral point voltage being in a constant state, and caus the voltage measurement unit 17 to measure the neutral point voltage measurement value Vmeas. The idling determination unit 22 acquires the neutral point voltage measurement value Vmeas obtained in step S324 as a reference voltage (step S325). At this time, in the voltage measurement unit 17, since the time (measurement time) from the measurement trigger Tr until completion of the measurement is short, the measurement is performed by turning on the measurement trigger Tr after elapse of the charging time. However, in this flowchart, for ease of explanation, a time from the start of the charge mode to the output of the measurement trigger signal is set as the charging time (S320 to S324). That is, the charging time in this flowchart is equal to or longer than a time measured in advance until the neutral point voltage after the transition to the charge mode becomes constant, and is equal to or shorter than a time obtained by subtracting the measurement time (S324 to S325) from the period (S320 to S325) the charge mode. Instead of the charging time, a trigger time may be used. When the trigger time is used, a trigger timer operat in parallel with the charge timer may be prepared in the state control unit 12, and the measurement trigger Tr may be turned on after the trigger time has elapsed. The trigger time is equal to or longer than a time measured in advance until the neutral point voltage after the transition to the charge mode becomes constant, and is equal to or shorter than a time obtained by subtracting the measurement time from the period the charge mode.

The state control unit 12 then transitions to the discharge mode (step S330). At this time, the discharging time of the discharge timer is reset and counting of a new discharging time is started in the state control unit 12 (step S331).

When the state control unit 12 generates the idling control signal Id in step S330, the switching elements Q1 to Q6 constituting the inverter circuit 2a are switched to the first switch state (step S332). That is, in response to the idling control signal Id, the switching elements Q1 to Q6 constituting the inverter circuit 2a enter again the first switch state, as illustrated in FIG. 6, for example. At this time, when the motor is idling, inductive kickback occurs in the inverter circuit. At this time, the mask time of the mask timer is reset and counting of a new mask time is started in the state control unit 12 (step S333).

The state control unit 12 determines whether a predetermined mask time has elapsed (step S334). When the predetermined mask time has elapsed (step S334: Yes), the state control unit 12 generates the measurement trigger signal Tr in order to cause the voltage measurement unit 17 to measure the neutral point voltage measurement value Vmeas because voltage fluctuation due to the inductive kickback occurs when the motor is idling, and causes the voltage measurement unit 17 to measure the neutral point voltage measurement value Vmeas (step S335). The idling determination unit 22 sets the neutral point voltage measurement value Vmeas obtained in step S35 as the measured voltage (step S336).

The state control unit 12 determines whether a predetermined discharging time has elapsed (step S337). When the predetermined discharging time has elapsed (step S337: Yes), the state control unit 12 enters the free mode (step S340).

After step S340, the idling determination unit 22 determines whether there is a voltage fluctuation based on the difference between the reference voltage acquired in step S325 and the measured voltage acquired in step S336 (step S341). The idling determination unit 22 can determine the motor 3 by determining a voltage fluctuation when the difference between the reference voltage acquired in step S325 and the measured voltage acquired in step S336 is larger than a predetermined idling threshold value.

When a voltage fluctuation (step S341: YES), the idling determination unit 22 determines the motor 3.

On the other hand, when no voltage fluctuation (step S341: NO), the idling determination unit 22 determines the motor 3 (not idling). The idling determination unit 22 generates an idling determination signal indicating the idling determination result. The idling determination signal is used by the state control unit 12.

Returning to FIG. 14, the state control unit 12 determines from the generated idling determination signal whether the motor 3 is determined to be idling (step S130), and when the motor 3 is determined to be idling (step S130: YES), the state control unit 12 executes driving of the motor idling by sensorless drive. On the other hand, when the motor is determined to be not idling (step S130: NO), the state control unit 12 executes driving and other operations of the stopped motor by braking, excitation, or forced commutation start. At this time, re-detection of the idling may also be performed.

### SECOND EMBODIMENT

Next, a motor unit 100A including a motor drive control device 1A according to a second embodiment will be described. In the first embodiment, the discharging time the duration of the discharge mode is set to a fixed time, and the discharge mode is ended when the elapsed time from the start of the discharge mode exceeds the set fixed time. In the second embodiment, instead of setting the discharging time, the duration of the discharge mode, to a fixed time, a current generated a shunt resistor Rs provided between the inverter circuit 2a and the ground is measured, and the discharge mode is ended when the measured current converges to a predetermined value or less. The configuration in the second embodiment, other than the configuration related to the determination of the end of the discharge mode, is configured in the same manner as the configuration of the first embodiment. The motor unit 10A including the motor drive control device 100A according to the second embodiment will be described below with respect to a configuration different from the configuration of the first embodiment. The same configurations as those of the motor unit 10 including the motor drive control device 100 according to the first embodiment are denoted by the same reference signs, and the descriptions thereof will be omitted.

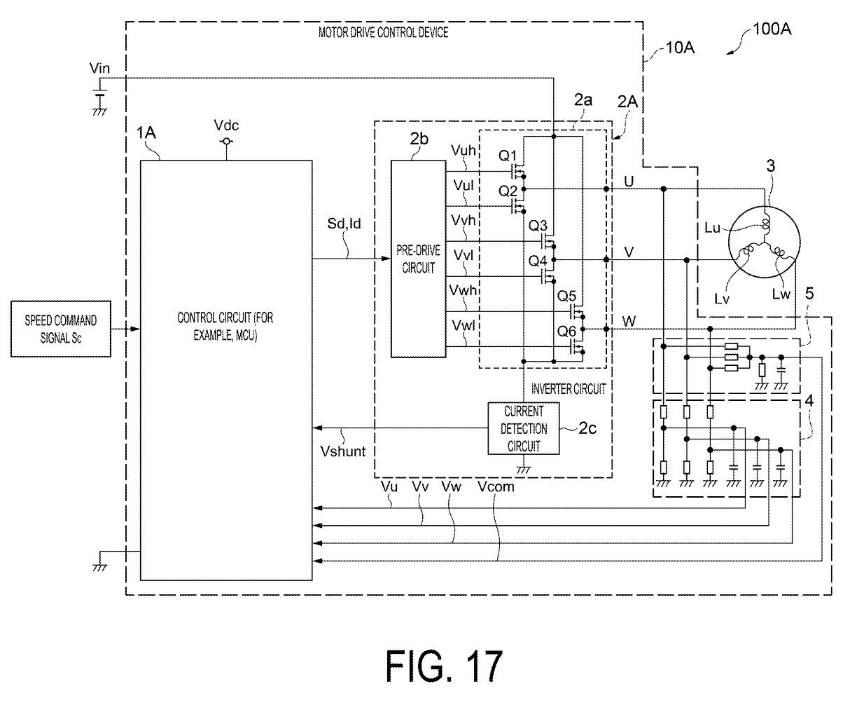

FIG. 17 is a diagram illustrating a configuration of the motor unit 100A including the motor drive control device 10A according to the second embodiment.

As illustrated in FIG. 17, the motor unit 100A of the present embodiment includes a motor 3 and the motor drive control device 10A for controlling rotation of the motor 3. The motor 3 has the same configuration as of the first embodiment, and thus the description thereof will be omitted.

As in the motor drive control device 10 of the first embodiment, the motor drive control device 10A periodically supplies the drive current (outputs the drive control signal Sd) to the 3-phase coils Lu, Lv, and Lw of the motor 3 to rotate the rotor of the motor 3 in order to drive the motor 3.

The motor drive control device 10A includes a control circuit 1A, a drive circuit 2A, a phase voltage detection circuit 4, and a neutral point voltage detection circuit 5. The phase voltage detection circuit 4 and the neutral point voltage detection circuit 5 have the same configurations as those of the first embodiment, and thus the descriptions thereof will be omitted.

The drive circuit 2A drives the motor 3 based on the drive control signal Sd output from the control circuit 1A described below. The drive circuit 2 includes, for example, an inverter circuit 2a, a pre-drive circuit 2b, and a current detection circuit 2c. The inverter circuit 2a and the pre-drive circuit 2b have the same configurations as those of the first embodiment.

The current detection circuit 2c is connected to a DC line of the inverter circuit 2a and detects the current flowing through the DC line. Specifically, the current detection circuit includes one resistor (hereinafter referred to also as "shunt resistor") Rs serving as a current detection element. The shunt resistor Rs is connected in series to the inverter circuit 2a between the DC power supply Vin and the ground potential, for example. That is, the shunt resistor Rs of the current detection circuit 2c is connected to a negative side (ground side) of the inverter circuit 2a, for example, as illustrated in FIG. 17. During driving of the motor, the inverter circuit 2a is controlled, and currents Iu, Iv, and Iw flowing through the three-phase coils Lu, Lv, and Lw of the motor 3 flow through the shunt resistor Rs of the current detection circuit 2c. The current detection circuit 2c detects a voltage drop caused by the current flowing through the shunt resistor Rs, from a differential voltage across both ends of the shunt resistor Rs, and outputs, as a detection result, a current detection signal Vshunt corresponding to the current flowing through the shunt resistor Rs to the control circuit 1A.

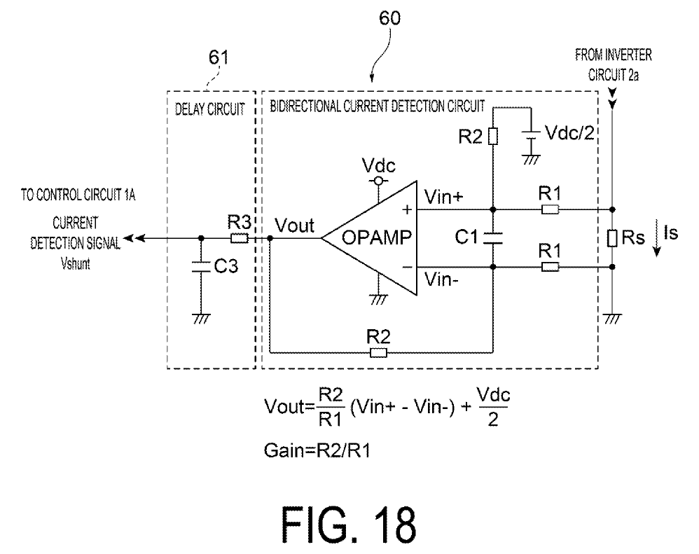

FIG. 18 is a diagram illustrating an example of a configuration of the current detection circuit 2c of the motor drive control device 10A. In addition to the shunt resistor Rs, the current detection circuit 2c includes a bidirectional current detection circuit 60 and a delay circuit 61.

The current detection circuit 2c in FIG. 18 outputs the current detection signal Vshunt corresponding to the current flowing through the shunt resistor Rs. Specifically, the bidirectional current detection circuit 60 in FIG. 18 acquires a differential voltage across both ends of the shunt resistor Rs, amplifies the acquired voltage by a predetermined gain with an amplifier unit using a differential amplifier circuit, and outputs the amplified voltage as a voltage drop signal Vout in the shunt resistor Rs. The delay circuit 61 smoothens the voltage drop signal Vout with a circuit composed of a resistor R3 and a capacitor C3, and outputs the smoothened signal to the control circuit 1 as the current detection signal Vshunt corresponding to the current flowing through the shunt resistor Rs. The bidirectional current detection circuit 60 is configured to be able to detect the positive and negative voltage drops generated at the shunt resistor Rs, i.e., to measure the bidirectional current by applying a voltage offsetting the output of the amplifier to a positive terminal of an OPAMP. Note that the voltage offsetting the output of the amplifier is not limited to Vdc/2, and the voltage offsetting the output of the amplifier may be applied to a negative terminal of the OPAMP.

Returning to FIG. 17, in driving the motor, the control circuit 1A generates the drive control signal Sd for driving the motor 3 based on, for example, the speed command signal Sc input from the outside and indicating a target operation state of the motor 3, and controls the drive of the motor 3. Specifically, the control circuit 1A generates the drive control signal Sd such that the motor 3 enters an operation state specified by the speed command signal Sc, and provides the generated drive control signal Sd to the drive circuit 2A.

In the idling detection of the motor, the control circuit 1A generates an idling control signal Id described below instead of the drive control signal Sd and detects the idling of the motor 3. Specifically, when the motor 3 is not driven by the drive control signal Sd, the control circuit 1A generates the idling control signal Id such that each of the switching elements Q1 to Q6 of the inverter circuit 2a enters a switch state specified by the idling control signal Id, and provides the generated idling control signal Id to the drive circuit 2A.

Also in the control circuit 1A of the second embodiment, as in the control circuit 1 of the first embodiment described with reference to FIGS. 2-6, three modes (a free mode, a charge mode, and a discharge mode) for detecting idling of the motor 3 are set by switching, using the idling control signal Id, the switch state of the low-side switch or the high-side switch of each of the switching elements Q1 to Q6 of the inverter circuit 2a.

The control circuit 1 is a program processing device (e.g., a microcontroller) having a configuration. In the configuration, for example, a processor such as a CPU, various storage devices such as a RAM and a ROM, and peripheral circuits such as a counter (timer), an A/D conversion circuit, a D/A conversion circuit, a clock generation circuit, and an input/output I/F circuit are connected to each other via a bus or a dedicated line.

Note that the motor drive control device 10A may have a configuration. In the configuration, at least a part of the control circuit 1A and at least a part of the drive circuit 2A are packaged as one integrated circuit device (IC), or the control circuit 1A and the drive circuit 2A are separately packaged as individual integrated circuit devices.

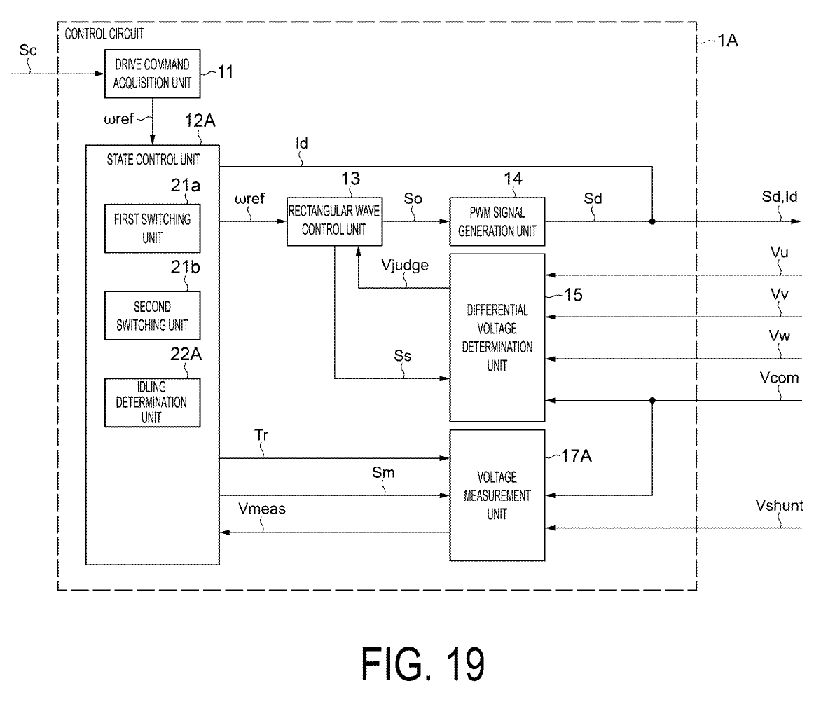

FIG. 19 is a diagram illustrating a functional block configuration of the control circuit 1A in the motor drive control device 10A according to the embodiment.

As illustrated in FIG. 19, the control circuit 1A includes, for example, a drive command acquisition unit 11, a state control unit 12A, a rectangular wave control unit 13, a PWM signal generation unit 14, and a differential voltage determination unit 15, as functional blocks for generating the drive control signal Sd in driving the motor by a 120-degree energization rectangular wave drive method. In addition, the control circuit 1A includes the state control unit 12A and a voltage measurement unit 17A, as functional blocks for generating the idling control signal Id in idling detection of the motor. The state control unit 12A includes a first switching unit 21a, a second switching unit 21b, and an idling determination unit 22A. Note that the drive command acquisition unit 11, the rectangular wave control unit 13, the PWM signal generation unit 14, the differential voltage determination unit 15, the first switching unit 21a, and the second switching unit 21b have the same configurations as those of the first embodiment, and thus the descriptions thereof will be omitted.

These functional blocks are implemented, for example, in a program processing device as the control circuit 1A, by the processor executing various arithmetic operations according to a program stored in a memory and controlling peripheral circuits such as a counter and an A/D conversion circuit.

The state control unit 12A is configured in the same manner as in the first embodiment except that the state control unit 12A includes an idling determination unit 22A instead of the idling determination unit 22 of the first embodiment. The idling determination unit 22A is configured in the same manner as in the first embodiment except for a configuration for causing the voltage measurement unit 17A to execute current offset measurement, a configuration for outputting the measurement voltage selection signal Sm, and a configuration for measuring a shunt current and terminating idling detection when the shunt current becomes equal to or less than a threshold value. In this case, the measurement voltage selection signal Sm is set so as to select the neutral point detection voltage Vcom when the signal is at the LO level, and to select the current detection signal Vshunt when the signal is at the HI level, for example.

In driving the motor, the state control unit 12A outputs the target rotational speed ωref as it is to the rectangular wave control unit 13. The state control unit 12A can determine how to start the motor when an idling determination signal described below is generated from the idling determination unit 22. Note that although not specifically illustrated in FIG. 19, the state control unit 12A may further include a function unit for executing such processing.

The state control unit 12A outputs a measurement trigger signal Tr to the voltage measurement unit 17A in idling detection of the motor. The measurement trigger signal Tr is a signal for triggering the measurement in the voltage measurement unit 17A, and for example, a signal for turning on and off a sampling circuit 172 within the voltage measurement unit 17A described below.

The voltage measurement unit 17A is an A/D converter digitiz a voltage of an input signal, and is configured to output, to the state control unit 12A, a voltage measurement value Vmeas corresponding to the neutral point detection voltage Vcom input from the neutral point voltage detection circuit 5 or a voltage measurement value Vmeas corresponding to the current detection signal Vshunt input from the current detection circuit 2c in idling detection of the motor.

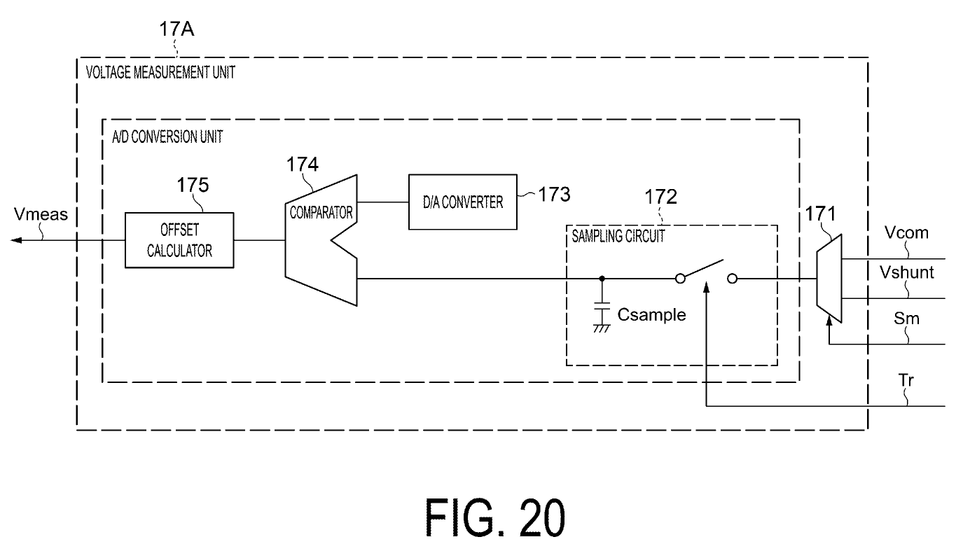

FIG. 20 is a diagram illustrating an example of a configuration of the voltage measurement unit 17A. Here, the example of the configuration of the voltage measurement unit 17A will be described. As illustrated in FIG. 20, for example, the voltage measurement unit 17A includes a multiplexer 171, a sampling circuit 172, a D/A converter 173, a comparator 174, and an offset calculator 175.

In idling detection of the motor, the voltage measurement unit 17A measures the voltage measurement value Vmeas corresponding to the neutral point detection voltage Vcom or the voltage measurement value Vmeas corresponding to the current detection signal Vshunt according to the measurement trigger signal Tr and the measurement voltage selection signal Sm input from the idling determination unit 22A of the state control unit 12A, and outputs the measured value Vmeas to the state control unit 12A.

In the voltage measurement unit 17A, the multiplexer 171 receives the neutral point detection voltage Vcom and the current detection signal Vshunt, and outputs, to the sampling circuit 172, a signal (the neutral point detection voltage Vcom or the current detection signal Vshunt) specified by the measurement phase voltage selection signal Sm input from the idling determination unit 22A of the state control unit 12A.

The sampling circuit 172 outputs, to the comparator 174, the signal (the neutral point detection voltage Vcom or the current detection signal Vshunt) input from the multiplexer 171 at a timing the measurement trigger signal Tr input from the idling determination unit 22A of the state control unit 12A is ON. In the voltage measurement unit 17A, the signal (the neutral point detection voltage Vcom or the current detection signal Vshunt) specified by the measurement phase voltage selection signal Sm is further processed by the comparator 174 and the offset calculator 175, and is finally output as the voltage measurement value Vmeas.

The idling determination controlled by the state control unit 12A will now be described further.

In the state control unit 12A, during idling detection of the motor, the first switching unit 21a generates the idling control signal Id for switching to the first switch state, the second switching unit 21b generates the idling control signal Id for switching to the second switch state, and the idling control signal Id is output to the drive circuit 2A. The start of the generation of the idling control signal Id can be triggered by reception of the speed command signal Sc after power-on, or after motor stop (after elapse of a predetermined time from interruption of the speed command signal Sc).

In the state control unit 12A, the first switching unit 21a generates the idling control signal Id switching the switching elements Q1 to Q6 constituting the inverter circuit 2a to the first switch state. In the state control unit 12A, the second switching unit 21b generates the idling control signal Id switching the switching elements Q1 to Q6 constituting the inverter circuit 2a to the second switch state. The idling control signal Id generated by the first switching unit 21a and the second switching unit 21b of the state control unit 12A is output to the drive circuit 2A.

In the state control unit 12A, to set a switch state enabling the idling detection of the motor, after power-on and until the speed command signal Sc is received by the drive command acquisition unit 11, the idling control signal Id corresponding to the free mode is generated by the first switching unit 21a, and start of driving of the motor is awaited. Thereafter, in the state control unit 12A, to detect the presence or absence of an idling state immediately before driving the motor by the input of the speed command signal Sc, the idling control signal Id is generated by the second switching unit 21b during a charging time (a period corresponding to the charge mode). Further thereafter, in the state control unit 12A, the idling control signal Id is generated again by the first switching unit 21a during a discharging time (a period corresponding to the discharge mode, not set to be constant in the present embodiment). Note that, after the discharging time, the idling control signal Id corresponding to the free mode may be generated again by the first switching unit 21a. In addition, in order to detect again the presence or absence of the idling state of the motor, the state control unit 12A may execute the charge mode and the discharge mode again immediately after transition to the free mode or after elapse of a predetermined waiting time.

Note that, in the present embodiment, in the state control unit 12A, the current offset measurement is performed after the idling control signal Id corresponding to the first free mode after power-on is generated and before the idling control signal Id corresponding to the charge mode is generated. In the current offset measurement, the idling determination unit 22A of the state control unit 12A outputs, to the voltage measurement unit 17A, the measurement trigger signal Tr for turning measurement ON and the measurement voltage selection signal Sm at an HI level for selecting measurement of the current detection signal Vshunt. The voltage measurement unit 17A receiv the measurement voltage selection signal Sm for selecting the current detection signal Vshunt and the measurement trigger signal Tr outputs the voltage measurement value Vmeas corresponding to the current detection signal Vshunt.

The transition timing from the free mode to the charge mode may be after the drive command acquisition unit 11 has received the speed command signal Sc, for example. After start of the idling detection and before transition to the charge mode, the idling determination unit 22A of the state control unit 12A outputs, to the voltage measurement unit 17A, the measurement voltage selection signal Sm at an LO level for selecting measurement of the neutral point detection voltage Vcom, and switches the voltage measurement value Vmeas output from the voltage measurement unit 17A from a value corresponding to the current detection signal Vshunt to a value corresponding to the neutral point detection voltage Vcom.

In idling detection of the motor, the state control unit 12A instructs the voltage measurement unit 17A to measure the input neutral point detection voltage Vcom by outputting the measurement trigger signal Tr for idling detection turn on a switch of the sampling circuit 172, at a timing immediately before transition from the charge mode to the discharge mode, i.e., in a state the neutral point voltage constant immediately before switching from the second switch state to the first switch state. Based on the instruction from the state control unit 12A, the voltage measurement unit 17A performs A/D conversion on the input neutral point detection voltage Vcom to generate the voltage measurement value Vmeas. The voltage measurement unit 17A outputs the generated voltage measurement value Vmeas to the idling determination unit 22A of the state control unit 12A. This voltage measurement value Vmeas is used as the reference voltage. After the measurement of the neutral point detection voltage Vcom, the mode transitions to the discharge mode.

In idling detection of the motor, the state control unit 12A instructs the voltage measurement unit 17A to measure the input neutral point detection voltage Vcom by outputting the measurement trigger signal Tr for idling detection turn on a switch of the sampling circuit 172 at a predetermined timing, in a discharge mode, that is, after switching from the second switch state to the first switch state and after elapse of a short mask time for avoiding an influence caused by switching of the switching elements. Based on the instruction from the state control unit 12A, the voltage measurement unit 17A performs A/D conversion on the input neutral point detection voltage Vcom to generate the voltage measurement value Vmeas. The voltage measurement unit 17A outputs the generated voltage measurement value Vmeas to the idling determination unit 22A of the state control unit 12A. This voltage measurement value Vmeas is used as the measured voltage. The measurement of the neutral point detection voltage Vcom is executed once during the period of the discharge mode.

The idling determination unit 22A determines whether the motor 3 is idling based on the voltage measurement value Vmeas generated by the voltage measurement unit 17A according to the neutral point detection voltage Vcom, and generates an idling determination signal indicating an idling determination result. Specifically, the idling determination unit 22A uses, as a measured voltage, the voltage measurement value Vmeas corresponding to the neutral point detection voltage Vcom and obtained by instructing the voltage measurement unit 17A to perform measurement at a predetermined timing, calculates a fluctuation voltage difference a difference between the reference voltage and the measured voltage, compares the calculated fluctuation voltage difference with a preset threshold value (an idling threshold value), and determines the motor 3 when the fluctuation voltage difference is greater than the idling threshold value.

As the idling threshold value, a fluctuation voltage difference a difference between the reference voltage and the measured voltage of the voltage measurement value Vmeas corresponding to the neutral point detection voltage Vcom at a minimum rotational speed idling detect (a minimum idling rotational speed) may be used.

As the charging time, a time measured in advance such that the voltage fluctuation difference at the minimum rotational speed idling detect (a minimum idling rotational speed) can be measured may be used, since the voltage fluctuation generated the neutral point voltage detection circuit 5 by the inductive kickback varies according to the rotational speed and the rotor position. As the charging time is shortened, the idling detection period is shortened, and the abnormal noise of the drive system caused by a short brake state during the charging time is reduced, is therefore preferable.

In the present embodiment, instead of setting the discharging time to a fixed time, a current generated the shunt resistor Rs provided between the inverter circuit and the ground is measured, and the discharge mode is ended when the measured current converges to a predetermined value or less. That is, one idling detection is ended. With this configuration, the minimum time corresponding to the circuit can be set as the discharging time, and thus the time can be shortened when the idling detection is performed a plurality of times.

Next, the transition of the mode after power-on of the state control unit 12A will be described in detail.

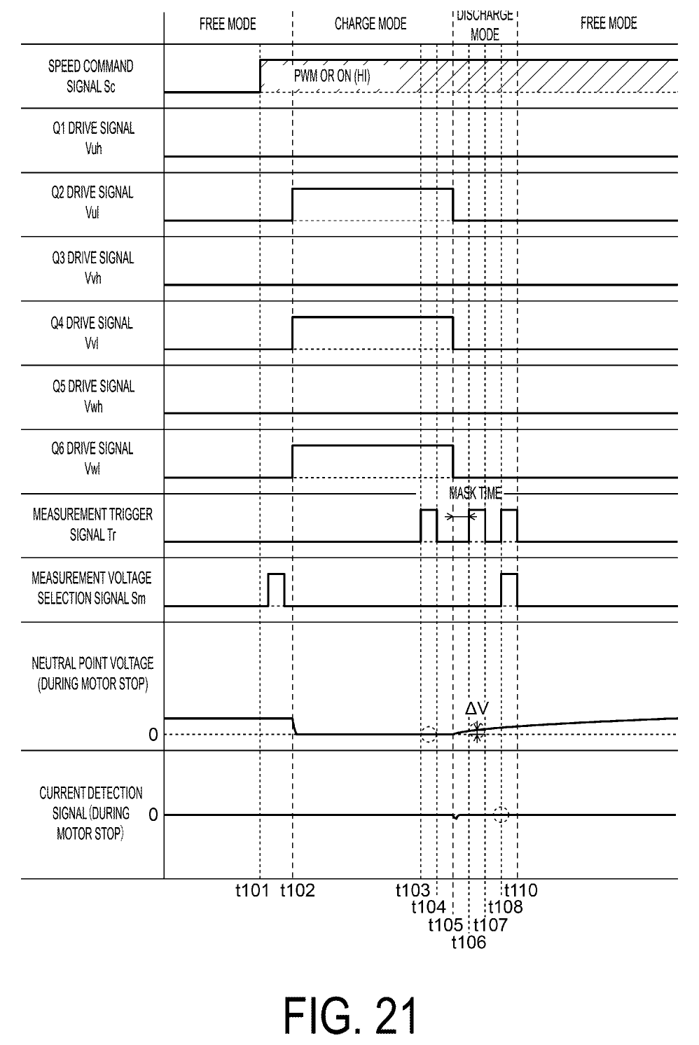

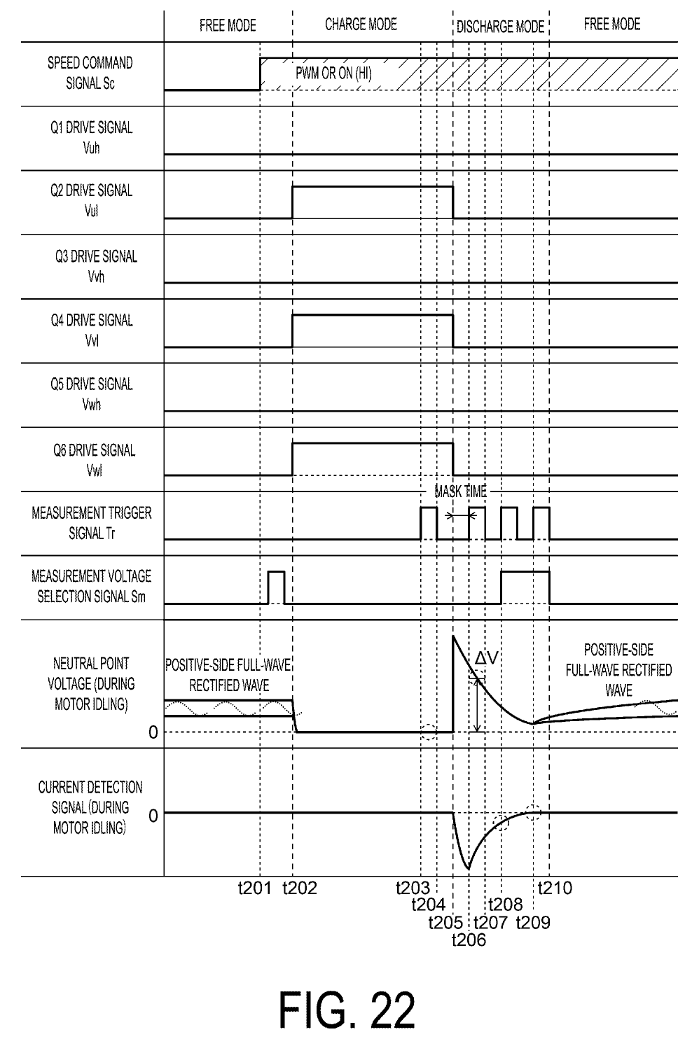

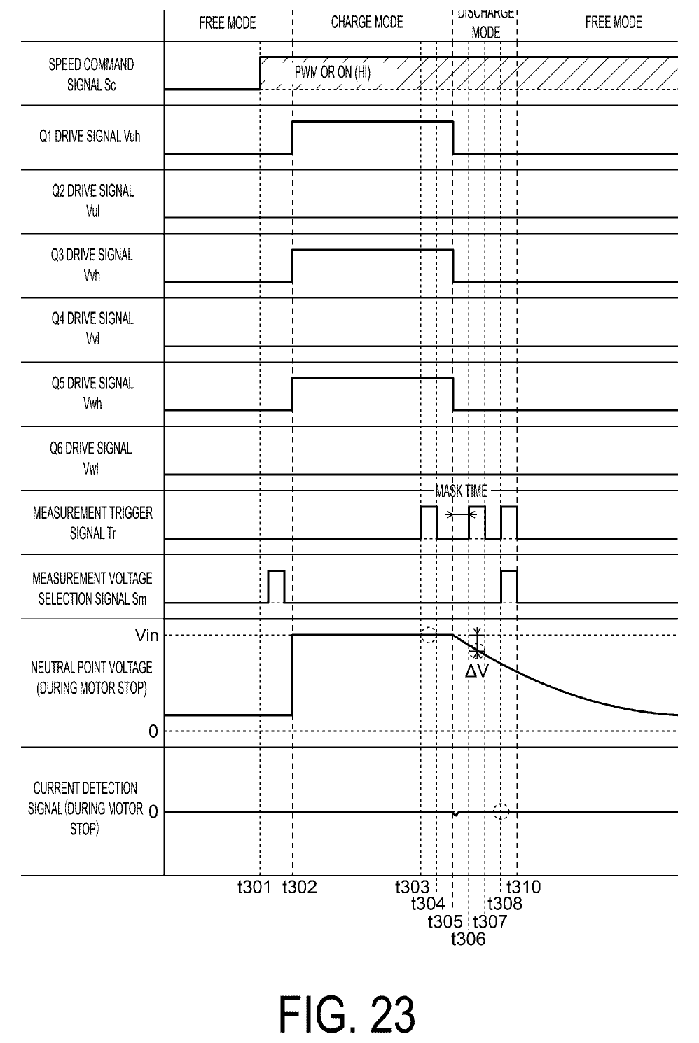

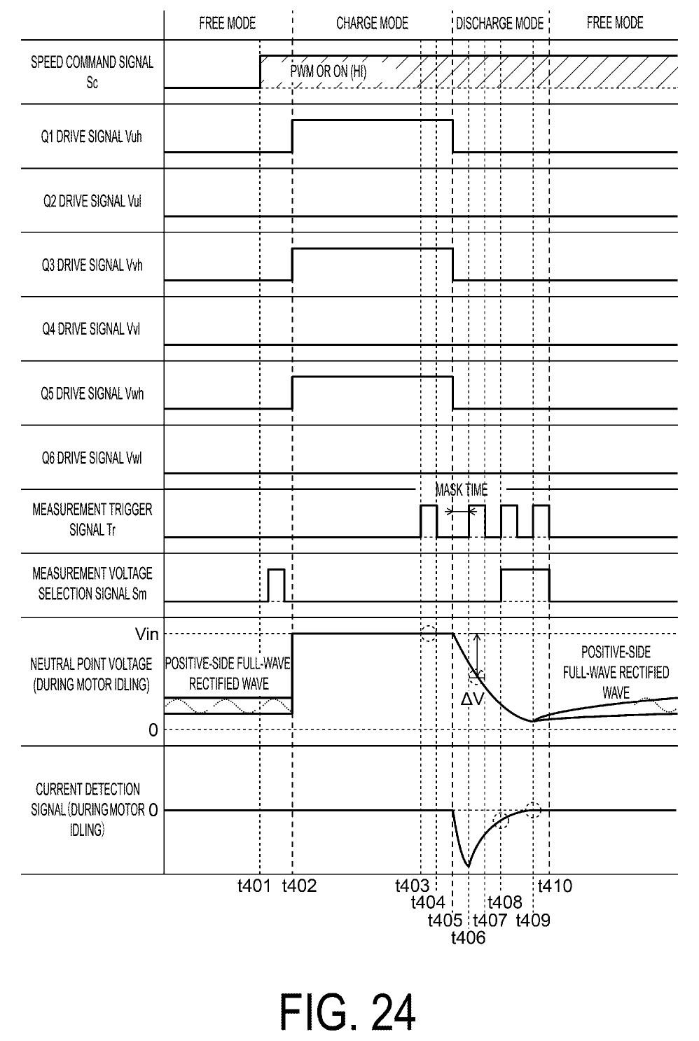

FIGS. 21-24 are timing charts illustrating an example of signal waveforms from power-on of the motor unit 100A, through input of the speed command signal Sc, until completion of idling determination. FIGS. 21 and 22 are timing charts when the idling detection is performed by switching of the low-side switches. FIGS. 23 and 24 are timing charts when the idling detection is performed by switching of the high-side switches. FIGS. 21 and 23 illustrate waveforms in a motor stop state, and FIGS. 22 and 24 illustrate waveforms in a motor idling state.

In FIGS. 21-24, waveforms of the speed command signal Sc, the respective drive signals input to the gates of the switching elements Q1 to Q6, the measurement trigger signal Tr for idling detection, the measurement voltage selection signal Sm, the neutral point voltage detection signal Vcom, and the current detection signal Vshunt are illustrated in order from the top.

The speed command signal Sc is a signal received as the target rotational speed ωref in the state control unit 12A, and the state control unit 12A, using reception of the speed command signal Sc as a trigger, generates the idling control signal Id including the respective drive signals input to the gates of switching elements Q1 to Q6 and the measurement trigger signal Tr for idling detection input to the voltage measurement unit 17A, at a predetermined timing.

In the examples illustrated in FIGS. 21-24, the motor drive control device 10A is shown to sequentially transition through the free mode, the charge mode, and the discharge mode, and then to return to the free mode again. At this time, the motor drive control device 10A starts from the free mode after power-on. Note that the timing charts illustrated in FIGS. 21-24 illustrate, as an example, the mode to the free mode again after the discharge mode, but no such limitation is intended.

In the free mode, the inverter circuit 2a is set to the first switch state by the idling control signal Id. Specifically, in response to the idling control signal Id generated by the first switching unit 21a, all the drive signals input to the gates of switching elements Q1 to Q6 constituting the inverter circuit 2a are set to low, and all switches of the inverter circuit are turned off. In this state, the closed circuit is not constituted, so the winding current of the coil (winding) is 0 (zero) A, and no current flows. At this time, no current flows through the shunt resistor Rs.

In this state, as illustrated in FIGS. 22 and 24, when the rotor of the motor 3 is idling, an induced electromotive force is generated the coils of the motor 3, and an induced voltage is periodically generated in the phase voltage of each phase. (Positive-side saddle wave) At this time, the neutral point voltage obtained by combining the phase voltages of all the phases is clamped by the parasitic diodes due to all the switching elements Q1 to Q6 being turned off, and thus oscillates as a positive-side full-wave rectified wave having an amplitude determined by the induced voltage corresponding to the idling rotational speed and a period of three times a period of the phase voltage.

In this state, as illustrated in FIGS. 21 and 23, when the rotor of the motor 3 is stopped, no induced electromotive force is generated the coils of the motor 3, and thus the neutral point voltage obtained by combining the phase voltages of all the phases changes to 0 (zero) V due to all the switching elements Q1 to Q6 being turned off. At this time, when an N-channel MOSFET is used at the HI side of the inverter circuit, a voltage applied by a circuit for boosting the gate voltage to be higher than the source voltage in order to turn on the FET may appear, and this voltage is illustrated in FIGS. 21 and 23.

Note that, in the present embodiment, before transition to the charge mode, the idling determination unit 22A outputs, to the voltage measurement unit 17A, the measurement voltage selection signal Sm at the LO level for specifying the neutral point detection voltage Vcom as the voltage measurement value Vmeas.

Next, in the charge mode, the inverter circuit 2a is set to the second switch state by the idling control signal Id. Specifically, by the idling control signal Id generated by the second switching unit 21b, all the drive signals input to the gates of the switching elements Q2, Q4, and Q6 of the lower arms or the switching elements Q1, Q3, and Q5 of the upper arms among the switching elements Q1 to Q6 constituting the inverter circuit 2a are set to high, and all the low-side switches (FIGS. 21 and 22) or all the high-side switches (FIGS. 23 and 24) of the inverter circuit are turned on.

In this state, when the rotor of the motor 3 is idling, induced electromotive forces are generated the coils of the motor 3, so that, as illustrated in FIGS. 3 and 5, a closed circuit is formed by the coils of the motor 3 and the switching elements Q2, Q4, and Q6 (FIG. 3) or the switching elements Q1, Q3, and Q5 (FIG. 5) turned on in the inverter circuit 2a, and induced currents circulating between the coils of the motor 3 and the inverter circuit 2a are generated. At this time, since the shunt resistor Rs is not included in the closed circuit, no current flows through the shunt resistor Rs, regardless of whether the rotor of the motor 3 is idling.

In the charge mode, as illustrated in FIG. 3, when switching is performed by the switching elements Q2, Q4, and Q6 of the lower arms, the phase voltage of each phase changes to 0 (zero) V due to all the LO-side switching elements Q2, Q4, and Q6 being turned on, regardless of whether the motor is in the stop state (FIG. 21) or the idling state (FIG. 22). The neutral point voltage also changes to 0 (zero) V due to all the LO-side switching elements Q2, Q4, and Q6 being turned on.

In the charge mode, as illustrated in FIG. 5, when switching is performed by the switching elements Q1, Q3, and Q5 of the upper arms, the phase voltage of each phase changes to the power supply voltage Vin due to all the HI-side switching elements Q1, Q3, and Q5 being turned on, regardless of whether the motor is in the stop state (FIG. 23) or the idling state (FIG. 24). The neutral point voltage obtained by combining the phase voltages of all the phases also changes to the power supply voltage Vin due to all the HI-side switching elements Q1, Q3, and Q5 being turned on.

Before the duration of the charge mode expires, in any of FIGS. 21-24, in the state control unit 12A, the neutral point detection voltage Vcom is measured by the measurement trigger signal Tr and is set as the reference voltage. As illustrated in FIG. 3, when switching is performed by the switching elements Q2, Q4, and Q6 of the lower arms, a voltage corresponding to 0 (zero) V is measured, and as illustrated in FIG. 5, when switching is performed by the switching elements Q1, Q3, and Q5 of the upper arms, a voltage corresponding to the power supply voltage Vin is measured.

Next, in the discharge mode, the inverter circuit 2a is again set to the first switch state by the idling control signal Id. Specifically, due to the idling control signal Id generated by the first switching unit 21a, all the drive signals input to the gates of the switching elements Q1 to Q6 constituting the inverter circuit 2a are again set to low, and all the switches of the inverter circuit are turned off.

In this state, when the rotor of the motor 3 is idling, the induced currents circulating between the coils of the motor 3 and the inverter circuit 2a during the charge mode attempt to continue to flow through the coils, so the inductive kickback occurs in the inverter circuit 2a due to all the switching elements Q1 to Q6 being turned off. In addition, when the motor 3 is stopped, no inductive kickback occurs in the inverter circuit 2a. At this time, in the shunt resistor Rs, the current increasing in the direction of the inverter circuit 2a (inverter circuit direction) from the ground side is momentarily generated and converges to zero. When the rotor of the motor 3 is stopped, electromagnetic noise may be generated by switching of the switching element, but no current flows through the shunt resistor Rs.

In the discharge mode, the influence of the induc kickback generated the inverter circuit 2a on the neutral point voltage is different between the case where switching is performed by the switching elements Q2, Q4, and Q6 of the lower arms as illustrated in FIGS. 3 (FIG. 22) and the case where switching is performed by the switching elements Q1, Q3, and Q5 of the upper arms as illustrated in FIGS. 5 (FIG. 24) .

As illustrated in FIG. 3, when switching is performed by the switching elements Q2, Q4, and Q6 of the lower arms (FIG. 22), due to the inductive kickback generated the 2a, a voltage fluctuation in the positive direction also occurs in the neutral point voltage due to the inductive kickback. At this time, as the neutral point detection voltage Vcom measured by the measurement trigger signal Tr in the discharge mode, a voltage including the voltage fluctuation in the positive direction caused by the inductive kickback is measured. Note that when the rotor of the motor 3 is stopped, the state returns to the state of the free mode before the idling detection without the occurrence of the inductive kickback (FIG. 21).

As illustrated in FIG. 5, when switching is performed by the switching elements Q1, Q3, and Q5 of the upper arms (FIG. 24), due to the inductive kickback generated the 2a, a voltage fluctuation in a negative direction also occurs in the neutral point voltage due to the inductive kickback. At this time, as the neutral point detection voltage Vcom measured by the measurement trigger signal Tr in the discharge mode, a voltage including the voltage fluctuation in the negative direction caused by the inductive kickback is measured. Note that when the rotor of the motor 3 is stopped, the state returns to the state of the free mode before the idling detection without the occurrence of the inductive kickback (FIG. 23).

It is understood that the voltage corresponding to the difference ΔV between the reference voltage, the neutral point detection voltage Vcom measured in the charge mode, and the measured voltage, the neutral point detection voltage Vcom measured in the discharge mode, is clearly different between the case where the inductive kickback occurs due to the motor being idling (FIGS. 22 and 24) and the case where the inductive kickback does not occur due to the motor being stopped (FIGS. 21 and 23). In the present embodiment, when the voltage corresponding to the difference ΔV is larger than a predetermined idling threshold value, the motor is in an idling state.

After elapse of time from the measurement in the discharge mode, the neutral point voltage converges as the influence of inductive kickback is eliminated, and the coil of the motor and the inverter circuit do not form a closed circuit due to the discharge mode, so the influence of the induced voltage due to the idling of the motor appears, and the neutral point voltage returns to the oscillation having a waveform similar to the waveform in the state of the free mode before idling detection.

After the discharge mode, the free mode may come back again. In the free mode after the discharge mode, the inverter circuit 2a is set to the first switch state by the idling control signal Id. Specifically, in response to the idling control signal Id generated by the first switching unit 21a, all the drive signals input to the gates of the switching elements Q1 to Q6 constituting the inverter circuit 2a are set to low, and all switches of the inverter circuit are turned off. In this state, the closed circuit is not formed, so the winding current of the coil (winding) is 0 (zero) A, and no current flows.

In the free mode again, the neutral point voltage is clamped by the parasitic diodes due to all the switching elements Q1 to Q6 being turned off, and thus returns to the oscillation as a positive-side full-wave rectified wave having an amplitude determined by the induced voltage corresponding to the idling rotational speed and a period of three times a period of the phase voltage, while the voltage fluctuation due to the inductive kickback converges.

The idling determination unit 22A receives the voltage measurement value Vmeas corresponding to the neutral point detection voltage Vcom described above from the voltage measurement unit 17A. As described above, the idling determination unit 22A measures the voltage measurement value Vmeas once during the charge mode and once during the discharge mode, and performs the idling determination based on the difference between the voltage measurement value Vmeas during the discharge mode and the voltage measurement value Vmeas during the charge mode, used as the reference voltage.

During the discharging time corresponding to the circuit, the state control unit 12A performs the measurement of the voltage measurement value Vmeas once after elapse of the predetermined mask time. For example, idling determination may be performed by using, as the reference voltage, a voltage measurement value Vmeas measured in advance in the charge mode, using, as the measured voltage, a voltage measurement value Vmeas measured in the discharge mode, and comparing a difference between the reference voltage and the measured voltage with a preset idling threshold value. The idling determination unit 22A may determine the motor 3 when the difference between the reference voltage and the measured voltage exceeds the preset idling threshold value. The idling threshold value may be a value such that the difference between the reference voltage and the measured voltage of the voltage measurement value Vmeas can be determined at the minimum idling rotational speed idling detect

To detect the discharging time corresponding to the circuit, the state control unit 12A measures a current generated the shunt resistor Rs provided between the inverter circuit and the ground, and ends the discharge mode when the measured current converges to a predetermined value or less. Specifically, the state control unit 12A acquires the voltage measurement value Vmeas obtained by measuring the current detection signal Vshunt corresponding to the current flowing through the shunt resistor Rs of the current detection circuit 2c with the voltage measurement unit 17A, and ends the discharge mode when the voltage measurement value Vmeas converges to a predetermined value or less.

Next, the flow of each processing in idling detection by the control circuit 1A of the motor drive control device 10A according to the second embodiment will be described.

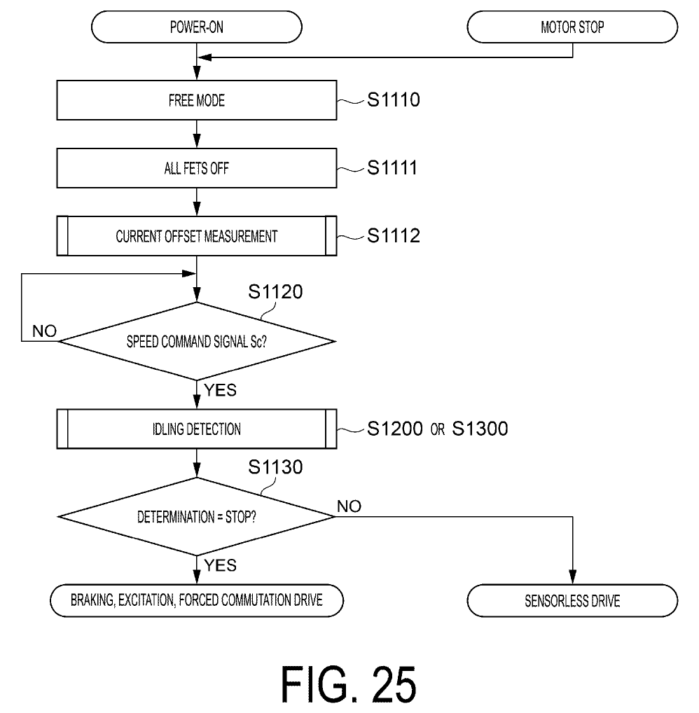

FIG. 25 is a flowchart illustrating an example of a flow of processing upon power-on in the control circuit 1A of the motor drive control device 10A according to the embodiment.

First, when the power is supplied to the motor drive control device 10A, as illustrated in FIG. 25, if switching to the free mode is determined in the state control unit 12A (step S1110), the first switching unit 21a generates the idling control signal Id for switching to the first switch state (all the switching elements Q1 to Q6 off) in order to set the switching elements Q1 to Q6 constituting the inverter circuit 2a to a switch state corresponding to the free mode (step S1111).

The state control unit 12A generates the idling control signal Id for switching the switching elements Q1 to Q6 constituting the inverter circuit 2a to the first switch state according to the idling control signal Id generated in step S1111. According to this idling control signal Id, the switching elements Q1 to Q6 constituting the inverter circuit 2a enter the first switch state illustrated in FIG. 2.

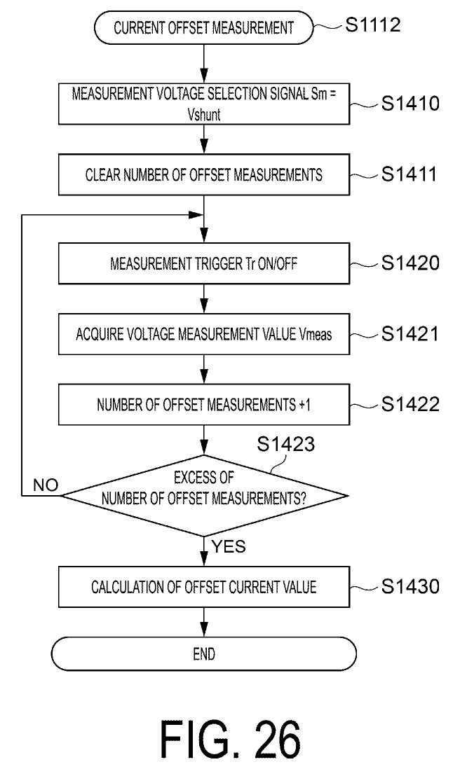

After entering the first switch state, the state control unit 12A executes offset measurement processing (step S1112). Now, the offset measurement processing of FIG. 26 is described.

First, when the offset measurement processing is started, the state control unit 12A instructs measurement of the current detection signal Vshunt by the measurement voltage selection signal Sm (step S1410). Specifically, the idling determination unit 12A of the state control unit 22A generates the measurement voltage selection signal Sm at the HI level for selecting the current detection signal Vshunt, and outputs the generated signal to the voltage measurement unit 17A.

Subsequently, the state control unit 12A clears a counter for the number of offset measurements and disables the offset calculator 175 (step S1411).

After step S1411, the state control unit 12A outputs the idling trigger signal Tr to the sampling circuit 172 of the voltage measurement unit 17A (step S1420). When the sampling circuit 172 of the voltage measurement unit 17A ha received the idling trigger signal Tr is switched, the voltage measurement unit 17A generates a voltage measurement value Vmeas corresponding to the current flowing through the shunt resistor Rs. The idling determination unit 22A of the state control unit 12A acquires the voltage measurement value Vmeas generated by the voltage measurement unit 17A (step S1421). Note that the current flowing through the shunt resistor Rs at this time is zero, but the voltage measurement value Vmeas corresponding to the current flowing through the shunt resistor Rs becomes a value other than zero due to the voltage offsetting the amplifier of the bidirectional current detection circuit 60.

When the voltage measurement value Vmeas is acquired in step S1421, the state control unit 12A increments the counter for the number of offset measurements by "+1" (step S1422).

The state control unit 12A determines whether the number of current offset measurements exceeds a predetermined number of offset measurements by confirming the counter for the number of offset measurements (step S1423).

When the number of current offset measurements does not exceed the predetermined number of offset measurements (step S1423: No), the processing returns to step S1420. On the other hand, when the number of current offset measurements exceeds the predetermined number of offset measurements (step S1423: Yes), an average value of the values acquired in the measurement of step S1421 is acquired as an offset current value, and the offset calculator is enabled (step S1430).

Returning to FIG. 25, after power-on or after the motor stops, the state control unit 12A determines whether the speed command signal Sc has been received in the drive command acquisition unit 11, in order to wait for start of driving of the motor. The state control unit 12A repeats the determination until the speed command signal Sc is received in the drive command acquisition unit 11.

the drive command acquisition unit 11 receives the speed command signal Sc from the host device (step S1120: YES), the state control unit 12A executes idling detection in order to detect the presence or absence of the idling state immediately before driving the motor (step S1200 or step S1300).

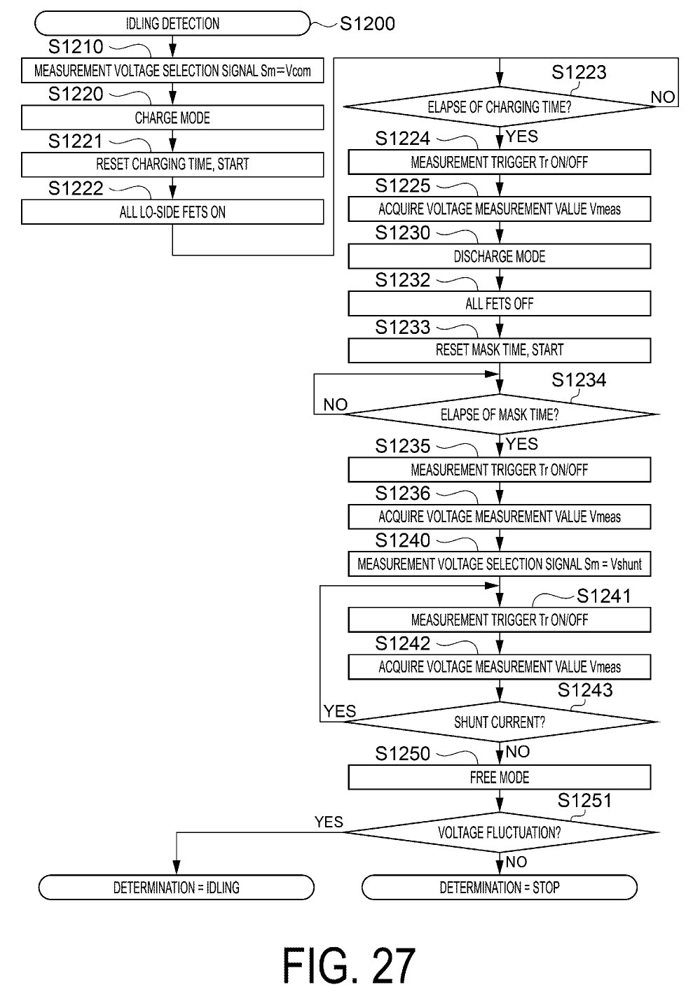

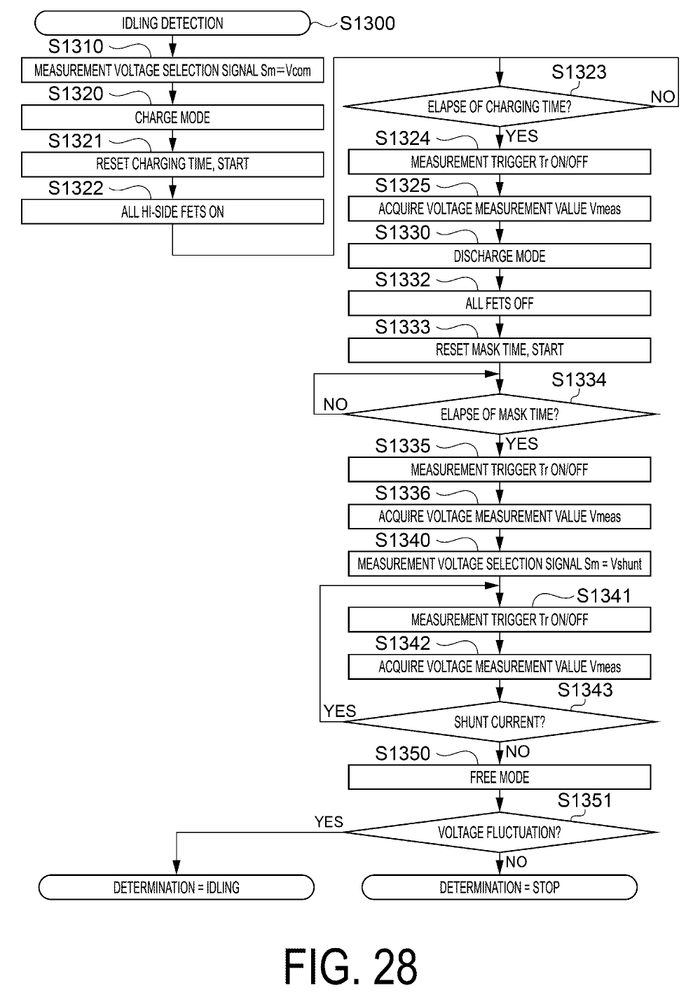

FIGS. 27 and 28 are flowcharts illustrating an example of the flow of idling detection processing by the control circuit 1A of the motor drive control device 10A. FIG. 27 is a flowchart when switching of the low-side switches is performed, and FIG. 28 is a flowchart when switching of the high-side switches is performed.

First, the idling detection when switching of the low-side switches is performed will be described with reference to FIG. 27.

When the idling detection of step S1200 is started, the state control unit 12A outputs, to the voltage measurement unit 17A, the measurement voltage selection signal Sm at the LO level for selecting the neutral point voltage Vcom (step S1210). The state control unit 12A then transitions to the charge mode (step S1220).

When the charge mode is entered, the charging time of the charge timer is reset and counting of a new charging time is started in the state control unit 12A (step S1221).

The state control unit 12A generates the idling control signal Id for switching the switching elements Q1 to Q6 constituting the inverter circuit 2a to the second switch state according to the idling control signal Id generated in step S1220. In response to the idling control signal Id, the switching elements Q1 to Q6 constituting the inverter circuit 2a enter the second switch state all the low-side switches Q2, Q4, and Q6 turned on, as illustrated in FIG. 3, for example (step S1222).

The state control unit 12A determines whether a predetermined charging time has elapsed after the idling control signal Id is generated in step S1220 (step S1223).

When the predetermined charging time has elapsed after the idling control signal Id is generated (step S1223: Yes), the state control unit 12A generates the measurement trigger signal Tr (step S1224) in order to cause the voltage measurement unit 17A to measure the voltage measurement value Vmeas as a reference voltage serv as a reference with the neutral point voltage being in a constant state, and causes the voltage measurement unit 17A to measure the voltage measurement value Vmeas corresponding to the neutral point voltage Vcom. The idling determination unit 22A acquires the voltage measurement value Vmeas obtained in step S1224 as a reference voltage (step S1225). At this time, in the voltage measurement unit 17A, since the time (measurement time) from the measurement trigger Tr until completion of the measurement is short, the measurement is performed by turning on the measurement trigger Tr after elapse of the charging time. However, in this flowchart, for ease of explanation, a time from the start of the charge mode to the output of the measurement trigger signal is set as the charging time (S1220 to S1224). That is, the charging time in this flowchart is equal to or longer than a time measured in advance until the neutral point voltage after the transition to the charge mode becomes constant, and is equal to or shorter than a time obtained by subtracting the measurement time (S1224 to S1225) from the period (S1220 to S1225) the charge mode. Instead of the charging time, a trigger time may be used. When the trigger time is used, a trigger timer operat in parallel with the charge timer may be prepared in the state control unit 12A, and the measurement trigger Tr may be turned on after the trigger time has elapsed. The trigger time is equal to or longer than a time measured in advance until the neutral point voltage after the transition to the charge mode becomes constant, and is equal to or shorter than a time obtained by subtracting the measurement time from the period the charge mode.

The state control unit 12A then transitions to the discharge mode (step S1230).

When the state control unit 12A generates the idling control signal Id in step S1230, the switching elements Q1 to Q6 constituting the inverter circuit 2a are switched to the first switch state (step S1232). That is, in response to the idling control signal Id, the switching elements Q1 to Q6 constituting the inverter circuit 2a enter again the first switch state, as illustrated in FIG. 4, for example. At this time, when the motor is idling, inductive kickback occurs in the inverter circuit. At this time, the mask time of the mask timer is reset and counting of a new mask time is started in the state control unit 12A (step S1233).

The state control unit 12A determines whether a predetermined mask time has elapsed (step S1234). When the predetermined mask time has elapsed (step S1234: Yes), the state control unit 12A generates the measurement trigger signal Tr in order to cause the voltage measurement unit 17A to measure the voltage measurement value Vmeas corresponding to the neutral point voltage Vcom because voltage fluctuation due to the inductive kickback occurs when the motor is idling, and causes the voltage measurement unit 17A to measure the voltage measurement value Vmeas corresponding to the neutral point voltage Vcom (step S1235). The idling determination unit 22A sets the voltage measurement value Vmeas obtained in step S1235 as the measured voltage (step S1236).

To detect the end of the discharging time, the state control unit 12A outputs, to the voltage measurement unit 17A, the measurement voltage selection signal Sm at the HI level for selecting the current detection signal Vshunt (step S1240).

The state control unit 12A generates the measurement trigger signal Tr (step S1241), and causes the voltage measurement unit 17A to measure the voltage measurement value Vmeas corresponding to the current detection signal Vshunt. The idling determination unit 22A acquires the voltage measurement value Vmeas obtained in step S1241 (step S1242), and determines whether there is a shunt current based on the voltage measurement value Vmeas acquired in step S1242 (step S1243). The presence or absence of the shunt current is determined based on whether the voltage measurement value Vmeas acquired in step S1242 is below a predetermined value.

When a shunt current (step S1243: YES), the state control unit 12A returns to step S1241 again and performs measurement. When no shunt current (step S1243: NO), the state control unit 12A enters the free mode (step S1250) as in the case where the discharging time has elapsed.

After step S1250, the idling determination unit 22A determines whether there is a voltage fluctuation based on the difference between the reference voltage acquired in step S1225 and the measured voltage acquired in step S1236 (step S1251). The idling determination unit 22A can determine the motor 3 by determining a voltage fluctuation when the difference between the reference voltage acquired in step S1225 and the measured voltage acquired in step S1236 is larger than a predetermined idling threshold value.

When a voltage fluctuation (step S1251: YES), the idling determination unit 22A determines that the motor 3 is in an idling state.

On the other hand, when it is determined that there is no voltage fluctuation (step S1251: NO), the idling determination unit 22A determines that the motor 3 is in a stop state (not idling). The idling determination unit 22A generates an idling determination signal indicating an idling determination result. The idling determination signal is used by the state control unit 12A.

Next, the idling detection when switching of the high-side switches is performed will be described with reference to FIG. 28.

When the idling detection of step S1300 is started, the state control unit 12A outputs, to the voltage measurement unit 17A, the measurement voltage selection signal Sm at the LO level for selecting the neutral point voltage Vcom (step S1310). The state control unit 12A then transitions to the charge mode (step S1320).

When the charge mode is entered, the charging time of the charge timer is reset and counting of a new charging time is started in the state control unit 12A (step S1321).

The state control unit 12A generates the idling control signal Id for switching the switching elements Q1 to Q6 constituting the inverter circuit 2a to the second switch state according to the idling control signal Id generated in step S1320. In response to the idling control signal Id, the switching elements Q1 to Q6 constituting the inverter circuit 2a enter the second switch state all the high-side switches Q1, Q3, and Q5 turned on, as illustrated in FIG. 5, for example (step S1322).

The state control unit 12A determines whether a predetermined charging time has elapsed after the idling control signal Id is generated in step S1320 (step S1323).

When the predetermined charging time has elapsed after the idling control signal Id is generated (step S1323: Yes), the state control unit 12A generates the measurement trigger signal Tr (step S1324) in order to cause the voltage measurement unit 17A to measure the voltage measurement value Vmeas as a reference voltage serv as a reference with the neutral point voltage being in a constant state, and caus the voltage measurement unit 17A to measure the voltage measurement value Vmeas corresponding to the neutral point voltage Vcom. The idling determination unit 22A acquires the voltage measurement value Vmeas obtained in step S1324 as a reference voltage (step S1325). At this time, in the voltage measurement unit 17A, since the time (measurement time) from the measurement trigger Tr until completion of the measurement is short, the measurement is performed by turning on the measurement trigger Tr after elapse of the charging time. However, in this flowchart, for ease of explanation, a time from the start of the charge mode to the output of the measurement trigger signal is set as the charging time (S1320 to S1324). That is, the charging time in this flowchart is equal to or longer than a time measured in advance until the neutral point voltage after the transition to the charge mode becomes constant, and is equal to or shorter than a time obtained by subtracting the measurement time (S1324 to S1325) from the period (S1320 to S1325) the charge mode. Instead of the charging time, a trigger time may be used. When the trigger time is used, a trigger timer operat in parallel with the charge timer may be prepared in the state control unit 12A, and the measurement trigger Tr may be turned on after the trigger time has elapsed. The trigger time is equal to or longer than a time measured in advance until the neutral point voltage after the transition to the charge mode becomes constant, and is equal to or shorter than a time obtained by subtracting the measurement time from the period the charge mode.

The state control unit 12A then transitions to the discharge mode (step S1330).

When the state control unit 12A generates the idling control signal Id in step S1330, the switching elements Q1 to Q6 constituting the inverter circuit 2a are switched to the first switch state (step S1332). That is, in response to the idling control signal Id, the switching elements Q1 to Q6 constituting the inverter circuit 2a enter again the first switch state, as illustrated in FIG. 6, for example. At this time, when the motor is idling, inductive kickback occurs in the inverter circuit. At this time, the mask time of the mask timer is reset and counting of a new mask time is started in the state control unit 12A (step S1333).

The state control unit 12A determines whether a predetermined mask time has elapsed (step S1334). When the predetermined mask time has elapsed (step S1334: Yes), the state control unit 12A generates the measurement trigger signal Tr in order to cause the voltage measurement unit 17A to measure the voltage measurement value Vmeas corresponding to the neutral point voltage Vcom because voltage fluctuation due to the inductive kickback occurs when the motor is idling, and causes the voltage measurement unit 17A to measure the voltage measurement value Vmeas corresponding to the neutral point voltage Vcom (step S1335). The idling determination unit 22A sets the voltage measurement value Vmeas obtained in step S1335 as the measured voltage (step S1336).

To detect the end of the discharging time, the state control unit 12A outputs, to the voltage measurement unit 17A, the measurement voltage selection signal Sm at the HI level for selecting the current detection signal Vshunt (step S1340).

The state control unit 12A generates the measurement trigger signal Tr (step S1341), and causes the voltage measurement unit 17A to measure the voltage measurement value Vmeas corresponding to the current detection signal Vshunt. The idling determination unit 22A acquires the voltage measurement value Vmeas obtained in step S1341 (step S1342), and determines whether there is a shunt current based on the voltage measurement value Vmeas acquired in step S1342 (step S1343). The presence or absence of the shunt current is determined based on whether the voltage measurement value Vmeas acquired in step S1342 is below a predetermined value.

When a shunt current (step S1343: YES), the state control unit 12A returns to step S141 again and performs measurement. When no shunt current (step S1343: NO), the state control unit 12A enters the free mode (step S1350) as in the case where the discharging time has elapsed.

After step S1340, the idling determination unit 22A determines whether there is a voltage fluctuation based on the difference between the reference voltage acquired in step S1325 and the measured voltage acquired in step S1336 (step S1351). The idling determination unit 22A can determine the motor 3 by determining a voltage fluctuation when the difference between the reference voltage acquired in step S1325 and the measured voltage acquired in step S1336 is larger than a predetermined idling threshold value.

When a voltage fluctuation (step S1351: YES), the idling determination unit 22A determines the motor 3 in an idling state.

On the other hand, when no voltage fluctuation (step S1351: NO), the idling determination unit 22A determines the motor 3 in a stop state (not idling). The idling determination unit 22A generates an idling determination signal indicating an idling determination result. The idling determination signal is used by the state control unit 12A.

Returning to FIG. 25, the state control unit 12A determines from the generated idling determination signal whether the motor 3 is determined to be idling (step S1130), and when the motor 3 is determined to be idling (step S1130: YES), the state control unit 12A executes driving of the motor idling by sensorless drive. On the other hand, when the motor is determined to be not idling (step S1130: NO), the state control unit 12A executes driving and other operations of the stopped motor by braking, excitation, or forced commutation start. At this time, re-detection of the idling may also be performed.

The control circuit 1 of the motor drive control device 10 according to the embodiment includes the neutral point voltage detection circuit 5 for detecting the neutral point detection voltage Vcom obtained by combining phase voltages of all phases among the respective phase voltages generated between the inverter circuit 2a and the coils of the respective phases of the motor 3, and, when the rotor of the motor 3 is idling, generates induced currents circulating between the coils of the motor and the inverter circuit 2a by switching the switch state of each of the switching elements Q1 to Q6 of the inverter circuit. Thereafter, the control circuit 1 determines the motor 3 based on the neutral point detection voltage Vcom generated the neutral point voltage detection circuit due to the inductive kickback generated the inverter circuit when the path of the induced currents is interrupted.

Thus, the motor drive control device 10 can stably detect the presence or absence of the idling state of the motor 3 in a short time without using a position sensor.

In addition, in the motor drive control device 10 according to the above embodiment, the control circuit 1 includes: the first switching unit 21a configured to switch from the first switch state with all of the high-side switches and the low-side switches included in the inverter circuit 2a turned off to the second switch state with all of either the high-side switches or the low-side switches included in the inverter circuit 2a turned on; the second switching unit 21b configured to switch from the second switch state to the first switch state; and the idling determination unit 22 configured to determine the motor based on the neutral point detection voltage Vcom generated the neutral point voltage detection circuit 5 when switching from the second switch state to the first switch state.

This enables each of the switching elements Q1 to Q6 of the inverter circuit 2a to switch to the switch states corresponding to the three modes (free mode, charge mode, discharge mode) for detecting the idling of the motor 3, thereby allowing detection of the presence or absence of the idling state of the motor 3.

In addition, in the motor drive control device 10 according to the above embodiment, the idling determination unit 22 uses, as the reference voltage, the neutral point detection voltage detected the neutral point voltage detection circuit 5 in the second switch state.

Accordingly, since the neutral point voltage detection circuit 5 is not affected by the induced voltage in the second switch state, the idling determination unit 22 can use the neutral point detection voltage detected the neutral point voltage detection circuit 5 as the reference voltage for idling determination.

In addition, in the motor drive control device according to the above embodiment, upon switching from the second switch state to the first switch state, the neutral point detection voltage detected the neutral point voltage detection circuit 5 is used as a measured voltage, a difference between the reference voltage and the measured voltage is calculated, and when the calculated difference is larger than a predetermined idling threshold value, the motor is determined to be in an idling state.

Accordingly, the idling can be stably in the discharge mode by using voltage fluctuation of the phase voltage caused by the inductive kickback.

### EXPANSION OF EMBODIMENTS

The invention made by the present inventor has been specifically described above based on the embodiments, but the present invention is not limited to the embodiments, and it goes without saying that the present invention can be changed in various ways within the scope not departing from the gist of the present invention.

For example, the voltage measurement unit 17A of the second embodiment is provided with one A/D converter and the multiplexer 171, and the multiplexer 171 is configured to select which of the neutral point voltage Vcom and the current detection signal Vshunt is input to the A/D converter by the measurement voltage selection signal Sm. However, the voltage measurement unit 17A of the second embodiment may be configured by two A/D converters. In this case, the neutral point voltage Vcom and the current detection signal Vshunt are measured by two A/D converters, respectively, and which of the voltage measurement values Vmeas generated by the two A/D converters is to be output may be switched by the measurement voltage selection signal Sm.

Further, in the embodiments, the case the speed command signal Sc includ a target value (target rotational speed) of the rotational speed of the motor 3 has been exemplified, but no such limitation is intended. For example, the speed command signal Sc may be a torque command signal for specifying the torque of the motor 3.

In the embodiments, the motor drive control device 10 has been described based on an example with a position sensor not used, but a position sensor may be provided. Even in this case, the position sensor is used for driving the motor and is not required for detecting idling. As the position sensor, a Hall element outputting a Hall signal may be used, or other signals corresponding to the position of the rotor of the motor 3 may be input as rotor position detection signals instead of such Hall signals. For example, an encoder, a resolver, or the like may be provided such that the detection signal is input to the control circuit 1. The measurement circuit for each phase voltage may be configured so that the signals of an A/D converter or a comparator comparing each phase voltage with the neutral point voltage are input as the rotor position detection signals.

Further, in the embodiments, the control circuit 1 is not limited to the circuit configuration described above. Various circuit configurations configured to meet the purpose of the present invention may be applied to the control circuit 1.

In the embodiments, the charge mode and the discharge mode may be repeated periodically to detect whether the motor is idling and to wait the motor to stop.

Further, in the embodiment, the driving of the motor is not limited to 120-degree energization rectangular wave drive. 150-degree energization rectangular wave drive or sine wave drive may be used.

In the embodiments, the number of phases of the motor 3 driven by the motor drive control device 10 is not limited to 3 phases.

The flowchart described above is a specific example, and is not limited to this flowchart. For example, other processing may be inserted between steps, or parallel processing may be performed.

### REFERENCE SIGNS LIST

1, 1A: Control circuit,
2, 2A: Drive circuit,
2a: Inverter circuit,
2b: Pre-drive circuit,
2c: Current detection circuit,
3: Motor,
4: Phase voltage detection circuit,
5: Neutral point voltage detection circuit,
10, 10A: Motor drive control device,
11: Drive command acquisition unit,
12, 12A: State control unit,
13: Rectangular wave control unit,
14: PWM signal generation unit,
15: Differential voltage determination unit,
17, 17A: Voltage measurement unit,
21a: First switching unit,
21b: Second switching unit,
22, 22A: Idling determination unit,
152: Measurement phase selection multiplexer,
153: Comparator,
171: Multiplexer,
172: Sampling circuit,
173: D/A converter,
174: Comparator,
175: Offset calculator,
100, 100A: Motor unit,
Q1 to Q6: Switching element,
Sc: Speed command signal,
Sd: Drive control signal,
Id: Idling control signal,
ωref: Target rotational speed,
So: Drive command signal,
Ss: Differential voltage selection signal,
Tr: Measurement trigger signal,
Vjudge: Voltage determination signal,
Vmeas: Neutral point voltage measurement value,
Vcom: Neutral point detection voltage (combined signal),
Vdc: Control voltage,
Vin: DC power supply, Vuu, Vul, Vvu, Vvl, Vwu,
Vwl: Drive signal, Vu, Vv,
Vw: Phase detection voltage, Lu, Lv,
Lw: Coil, Iu, Iv,
Iw: Winding current, eu, ev,
ew: Induced voltage,
Vshunt: Current detection signal,
Sm: Measurement voltage selection signal,
Rs: Shunt resistor

1. A motor drive control device comprising:
a control circuit configured to generate a drive control signal drive a motor including a coil of at least one phase;
a drive circuit including an inverter circuit including a high-side switch and a low-side switch, the high-side switch and the low-side switch being provided corresponding to a coil of each phase of the motor and connected in series with each other, the drive circuit being configured to rotate a rotor of the motor by alternately turning the high-side switch and the low-side switch on and off in response to the drive control signal to switch an energization direction of the coil of corresponding phase; and
a neutral point voltage detection circuit configured to detect a neutral point detection voltage obtained by combining phase voltages of all phases among respective phase voltages generated between the inverter circuit and the coils of the respective phases of the motor, wherein
the control circuit generates an idling control signal instead of the drive control signal, and when the rotor of the motor is idling, generates induced currents circulating between the coils of the motor and the inverter circuit by switching a switch state of the inverter circuit, and then determines the motor based on a neutral point detection voltage generated the neutral point voltage detection circuit by inductive kickback generated the inverter circuit when a path of the induced currents is interrupted.

2. The motor drive control device according to claim 1, wherein
the control circuit includes:
a first switching unit configured to switch from a first switch state with all of the high-side switches and the low-side switches included in the inverter circuit turned off to a second switch state with all of either the high-side switches or the low-side switches included in the inverter circuit turned on;
a second switching unit configured to switch from the second switch state to the first switch state; and
an idling determination unit configured to determine the motor based on the neutral point detection voltage generated the neutral point voltage detection circuit when switching from the second switch state to the first switch state.

3. The motor drive control device according to claim 2, wherein
the idling determination unit sets, as a reference voltage, the neutral point detection voltage generated the neutral point voltage detection circuit in the second switch state.

4. The motor drive control device according to claim 3, wherein
when switching from the second switch state to the first switch state, the neutral point detection voltage detected the neutral point voltage detection circuit is used as a measured voltage, a difference between the reference voltage and the measured voltage is calculated, and when the calculated difference is larger than a predetermined idling threshold value, the motor is determined to be in an idling state.

5. The motor drive control device according to claim 4, further comprising:
a shunt resistor provided between the inverter circuit and a ground and
a current detection circuit configured to generate a current detection signal a voltage signal corresponding to a current flowing through the shunt resistor, wherein
the control circuit includes a voltage measurement unit configured to measure voltage value of the neutral point detection voltage and the current detection signal, and
the voltage measurement unit measures the voltage value of the neutral point detection voltage at a first timing when switching from the second switch state to the first switch state, and thereafter measures the voltage value of the current detection signal.

6. A method for detecting idling of a motor to be executed in a motor drive control device including:
a control circuit configured to generate a drive control signal drive a motor including a coil of at least one phase;
a drive circuit including an inverter circuit including a high-side switch and a low-side switch, the high-side switch and the low-side switch being provided corresponding to a coil of each phase of the motor and connected in series with each other, the drive circuit being configured to rotate a rotor of the motor by alternately turning the high-side switch and the low-side switch on and off in response to the drive control signal to switch an energization direction of the coil of corresponding phase; and
a neutral point voltage detection circuit configured to detect a neutral point detection voltage obtained by combining phase voltages of all phases among respective phase voltages generated between the inverter circuit and the coils of the respective phases of the motor, the method comprising:
a first step of switching from a first switch state with all of the high-side switches and the low-side switches included in the inverter circuit turned off to a second switch state with all of either the high-side switches or the low-side switches included in the inverter circuit turned on;
a second step of switching from the second switch state to the first switch state; and
a third step of determining the motor based on the neutral point detection voltage generated the neutral point voltage detection circuit when switching to the first switch state.
